(19) United States
(12) Patent Application Publication
(10) Pub. No.: US 2026/0372053 A1
(43) Pub. Date: Nov. 19, 2026

(54) SEMICONDUCTOR STRUCTURE AND PREPARATION METHOD THEREFOR, AND SEMICONDUCTOR DEVICE AND ELECTRONIC DEVICE

(71) Applicants: BEIJING INTELLECTUAL PROPERTY OPERATIONS MANAGEMENT CO., LTD., Beijing (CN); PEKING UNIVERSITY, Beijing (CN)

(72) Inventors: Heng WU, Beijing (CN); Runsheng WANG, Beijing (CN); Ming LI, Beijing (CN); Haoran LU, Beijing (CN); Jiacheng SUN, Beijing (CN); Ru HUANG, Beijing (CN)

(21) Appl. No.: 19/470,709

(22) PCT Filed: Aug. 7, 2024
(86) PCT No.: PCT/CN2024/110462

§ 371 Date: Sep. 29, 2025

(30) Foreign Application Priority Data
Aug. 7, 2023 (CN) 202310986859.3
Dec. 11, 2023 (CN) 202311694452.X
Dec. 11, 2023 (CN) 202311694549.0
Dec. 18, 2023 (CN) 202311740316.X

(51) Int. Cl. H10W 20/42; H10D 30/00; H10D 30/01; H10D 30/43; H10D 30/62; H10D 62/10; H10D 62/13; H10D 64/23; H10D 84/01; H10D 84/85; H10W 20/41

(52) U.S. Cl. CPC H10W 20/422; H10D 30/014; H10D 30/019; H10D 30/024; H10D 30/43; H10D 30/502; H10D 30/6211; H10D 62/121; H10D 62/151; H10D 64/254; H10D 84/017; H10D 84/0186; H10D 84/0188; H10D 84/851; H10D 84/853; H10D 84/856; H10W 20/435

(57) ABSTRACT

A semiconductor structure and a preparation method thereof, a semiconductor device, and an electronic equipment are provided. The preparation method includes: forming an active structure on a semiconductor substrate, wherein the active structure includes a first active structure and a second active structure; forming a first transistor based on the first active structure; wherein the first transistor includes a first source/drain structure, a first source/drain metal, and a first interlayer dielectric layer; performing flipping on the first transistor and removing the semiconductor substrate; forming a second transistor based on the second active structure; wherein the second transistor includes a second source/drain structure, a second source/drain metal, and a second interlayer dielectric layer; wherein the first source/drain metal is communicated with the second source/drain metal through an interconnect via structure, the interconnect via structure passes through the first interlayer dielectric layer and the second interlayer dielectric layer.

### CROSS-REFERENCE TO RELATED APPLICATION

The present disclosure is based on a Chinese patent application with the application number 202310986859.3 filed on Aug. 7, 2023, a Chinese patent application with the application number 202311694549.0 filed on Dec. 11, 2023, a Chinese patent application with the application number 202311740316.X filed on Dec. 18, 2023, a Chinese patent application with the application number 202311694452.X filed on Dec. 11, 2023, and claims priorities to these Chinese patent applications, the disclosure of which is hereby incorporated by reference in their entireties.

### TECHNICAL FIELD

The present disclosure relates to the field of semiconductors, and particularly relates to a semiconductor structure and a preparation method thereof, a semiconductor device, and an electronic equipment.

### BACKGROUND

As Moore's Law continues to deepen, continuing to promote the reduction of transistor size is a currently hot issue in research and development in the industry. Stacked transistors further increase transistor integration density by integrating two or more layers of transistors in vertical space, becoming one of the important technologies to continue the size reduction of integrated circuits.

The process of preparing stacked transistors adopts a monolithic scheme or a sequential scheme, both of which have the problems of difficulty and high complexity of the preparation process. Therefore, in order to simplify the process flow and reduce the difficulty of preparation, there is still a need for continuous improvement in the preparation process of the stacked transistors.

### SUMMARY

The present disclosure provides a semiconductor structure and a preparation method thereof, a semiconductor device, and an electronic equipment.

A first aspect of the present disclosure provides a preparation method of a semiconductor structure. The method includes: forming an active structure on a semiconductor substrate, wherein the active structure includes a first active structure and a second active structure; forming a first transistor based on the first active structure; where the first transistor includes a first source/drain structure, a first source/drain metal, and a first interlayer dielectric layer; performing flipping on the first transistor and removing the semiconductor substrate; forming a second transistor based on the second active structure; where the second transistor includes a second source/drain structure, a second source/drain metal, and a second interlayer dielectric layer; where the first source/drain metal is communicated with the second source/drain metal through an interconnect via structure, the interconnect via structure passes through the first interlayer dielectric layer and the second interlayer dielectric layer.

A second aspect of the present disclosure provides a semiconductor structure. The semiconductor structure may be prepared using the preparation method as described in the first aspect. including: a first transistor; a second transistor, the first transistor and the second transistor being disposed opposite to each other; where the first source/drain metal of the first transistor is communicated with the second source/drain metal of the second transistor through an interconnect via structure, the interconnect via structure passes through the first interlayer dielectric layer of the first transistor and the second interlayer dielectric layer of the second transistor.

A third aspect of the present disclosure provides a semiconductor device. The semiconductor device includes: a semiconductor structure as described in the second aspect.

A third aspect of the present disclosure provides an electronic equipment. The electronic equipment includes: a circuit board and a semiconductor device as described in the third aspect; the semiconductor device is disposed on the circuit board.

Compared with the related art, the present disclosure has the following beneficial effects:

In the embodiments of the present disclosure, the first transistor is formed based on the first portion of the active structure, and after clipping, the second transistor is formed based on the second portion of the active structure. In this way, the first transistor and the second transistor are disposed opposite to each other, and the first source/drain metal of the first transistor is communicated with the second source/drain metal of the second transistor through an interconnect via structure, the interconnect via structure passes through the first interlayer dielectric layer of the first transistor and the second interlayer dielectric layer of the second transistor. Thus, in the case where the first transistor and the second transistor are self-aligned, source/drain interconnection between the first transistor and the second transistor is achieved.

It should be understood that the above general description and the following detailed description are exemplary and explanatory only, and do not limit the present disclosure.

### BRIEF DESCRIPTION OF THE DRAWINGS

The accompanying drawings herein, which are incorporated into and constitute a part of the specification, illustrate embodiments consistent with the present disclosure and, together with the specification, serve to explain the principles of the embodiments of the present disclosure.

FIG. 1 is a schematic flow diagram of an implementation of a preparation method of a semiconductor structure according to an embodiment of the present disclosure.

FIG. 2 is a schematic structural diagram of a semiconductor structure according to an embodiment of the present disclosure.

FIG. 3A and FIG. 3B are schematic diagrams of a preparation process of the semiconductor structure in FIG. 2 according to an embodiment of the present disclosure.

FIG. 4 is a schematic structural diagram of a semiconductor structure according to an embodiment of the present disclosure.

FIG. 5 is a schematic structural diagram of a semiconductor structure according to an embodiment of the present disclosure.

FIG. 6 is a schematic structural diagram of a semiconductor structure according to an embodiment of the present disclosure.

FIG. 7A and FIG. 7B are schematic diagrams of a preparation process of the semiconductor structure in FIG. 6 according to an embodiment of the present disclosure.

FIG. 8 is a schematic structural diagram of a semiconductor structure according to an embodiment of the present disclosure.

FIG. 9 is a schematic structural diagram of a semiconductor structure according to an embodiment of the present disclosure.

FIG. 10 is a schematic structural diagram of a semiconductor structure according to an embodiment of the present disclosure.

FIG. 11 is a schematic structural diagram of a semiconductor structure according to an embodiment of the present disclosure.

FIG. 12 is a schematic structural diagram of an interconnect via structure according to an embodiment of the present disclosure.

FIG. 13A to FIG. 13E are schematic diagrams of a preparation process of the semiconductor structure in FIG. 11 according to an embodiment of the present disclosure.

FIG. 14 is a schematic structural diagram of a semiconductor structure according to an embodiment of the present disclosure.

FIG. 15 is a schematic structural diagram of an interconnect via structure according to an embodiment of the present disclosure.

FIG. 16 is a schematic structural diagram of a semiconductor structure according to an embodiment of the present disclosure.

FIG. 17 is a schematic structural diagram of a semiconductor structure according to an embodiment of the present disclosure.

FIG. 18 is a schematic structural diagram of a semiconductor structure according to an embodiment of the present disclosure.

FIG. 19 is a schematic structural diagram of a semiconductor structure according to an embodiment of the present disclosure.

FIG. 20 is a schematic structural diagram of a semiconductor structure according to an embodiment of the present disclosure.

FIG. 21 is a schematic structural diagram of an interconnect via structure according to an embodiment of the present disclosure.

FIG. 22A to FIG. 22G are schematic diagrams of a preparation process of the semiconductor structure in FIG. 20 according to an embodiment of the present disclosure.

FIG. 23 is a schematic structural diagram of a semiconductor structure according to an embodiment of the present disclosure.

FIG. 24 is a schematic structural diagram of a semiconductor structure according to an embodiment of the present disclosure.

FIG. 25 is a schematic diagram of a preparation process of the semiconductor structure in FIG. 20 according to an embodiment of the present disclosure.

FIG. 26 is a schematic structural diagram of a semiconductor structure according to an embodiment of the present disclosure.

FIG. 27A to FIG. 27F are schematic diagrams of a preparation process of the semiconductor structure in FIG. 26 according to an embodiment of the present disclosure.

FIG. 28 is a schematic diagram of a preparation process of the semiconductor structure in FIG. 26 according to an embodiment of the present disclosure.

FIG. 29 is a schematic structural diagram of a semiconductor structure according to an embodiment of the present disclosure.

FIG. 30 is a schematic structural diagram of a semiconductor structure according to an embodiment of the present disclosure.

FIG. 31 is a schematic structural diagram of a semiconductor structure according to an embodiment of the present disclosure.

FIG. 32 is a schematic structural diagram of a semiconductor structure according to an embodiment of the present disclosure.

FIG. 33 is a schematic structural diagram of a semiconductor structure according to an embodiment of the present disclosure.

### DESCRIPTION OF REFERENCE SIGNS:

Semiconductor structure 10; first transistor 11; first dummy gate sidewall 111; first source/drain structure 112; first interlayer dielectric layer 113; first gate structure 114; first source/drain metal 115; first metal interconnect layer 116; second transistor 12; second dummy gate sidewall 121; second source/drain structure 122; second interlayer dielectric layer 123; second gate structure 124; second source/drain metal 125; second metal interconnect layer 126; device area 13; field area 14; semiconductor substrate 20; first active structure 21; second active structure 22; shallow trench isolation structure 23; insulating layer 24; carrier wafer 25; photoresist 26; first dummy gate structure 28; second dummy gate structure 29; gate cut-off structure 30; anti-reflection layer 31; interconnect via structure 300; first interconnect via structure 301; second interconnect via structure 302; first deep groove 400; second groove 402; first interconnect sublayer 1251; second interconnect sublayer 1252.

### DETAILED DESCRIPTION

Description will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the embodiments of the present disclosure.

The terminology used in the embodiments of the present disclosure is for the purpose of describing particular embodiments only, and is not intended to limit the embodiments of the present disclosure. As used in the present disclosure, the singular forms “a/an”, “said” and “the” are also intended to include the multiple forms unless the context clearly indicates otherwise. It should also be understood that the term “and/or” as used herein refers to and includes any or all possible combinations of one or more associated listed items.

As Moore's Law continues to deepen, continuing to promote the reduction of transistor size is a currently hot issue in research and development in the industry. Stacked transistors, in which integration of two or more layers of transistors in vertical space may be implemented by means of three-dimensional transistor stacking, and which help to further increase transistor integration density and improve circuit performance, are considered to be one of the important technologies to continue the size reduction of integrated circuits.

In an embodiment, there are two schemes for the preparation process of stacked transistors, the first one is a monolithic scheme, and the second one is a sequential scheme. In the first scheme, processes such as exposure, etching and diffusion are repeated on the same substrate to prepare an N-channel field effect transistor (NFET) and a P-channel field effect transistor (PFET), so that two transistors are stacked vertically. However, the preparation process of the first scheme determines that transistors in the same layer of the stacked transistors have to be of the same type, and the transistors in the same layer must be strictly in the same planar space with no alignment deviation. The first scheme has the advantage of better integration density. The first scheme has the following two disadvantages: (1) the process is complex and requires a lot of development and optimization for the process technology; (2) the polarity of transistors in the same layer is fixed, and the formation of a basic complementary metal-oxide-semiconductor (CMOS) circuit has to rely on two layers of transistors, which leads to poor design flexibility. In the second scheme, a wafer is adhered on the upper part of the prepared bottom transistor to prepare the top transistor, so as to stack the two transistors vertically. However, the second scheme has the following technical challenges at present: (1) preparation of the high-quality active layer of the top transistor; (2) thinning and defect control of the bonding wafer for the top transistor; (3) alignment error between the upper and bottom transistors, which requires extremely high lithography accuracy.

The common technical difficulties faced by the above two schemes include: (1) the thermal stability of the bottom device when the top device is prepared; (2) performance of the top device at low thermal budget; (3) metal interconnection of transistors between the top layer and the bottom layer.

In order to solve the above technical problems, embodiments of the present disclosure provide a semiconductor structure and a preparation method thereof, so as to simplify the process flow of a stacked transistor and reduce manufacturing difficulty.

In the embodiments of the present disclosure, the semiconductor structure may be applied to a semiconductor device such as a memory, a processor, and the like. The semiconductor structure includes at least two transistors, which may be a bottom transistor and a top transistor. The bottom transistor and the top transistor are disposed opposite to each other. The first active area in the bottom transistor and the second active area in the top transistor are formed by the same process; here, it can be understood that the bottom transistor and the top transistor share an active structure.

In an embodiment, the source/drain metal in the bottom transistor and the source/drain metal in the top transistor may communicate with each other through an interconnect via structure. The interconnect via structure may pass through the interlayer dielectric layer in the bottom transistor and the interlayer dielectric layer in the top transistor, such that in the case where the first transistor and the second transistor are self-aligned, source/drain interconnection between the first transistor and the second transistor is achieved.

In some embodiments, two transistors in the semiconductor structure are stacked in the first direction, which may be the direction along the height of the active structure. Then, the arrangement direction (direction along the width) of the active structures may be the second direction, and the extension direction (direction along the longitude) of the active structures may be the third direction.

In an embodiment, the first direction is perpendicular to the second direction and the third direction; the second direction is perpendicular to the third direction.

The preparation method provided in the embodiments of the present disclosure will be described below in combination with the above semiconductor structure.

FIG. 1 is a schematic flow diagram of an implementation of a preparation method of a semiconductor structure according to an embodiment of the present disclosure. As shown in FIG. 1, the preparation method of a semiconductor structure may include:

In step S101, an active structure is formed on a semiconductor substrate, where the active structure includes a first active structure and a second active structure.

In some embodiments, the semiconductor substrate may be a silicon substrate, a silicon-on-insulator (SOI) substrate, and of course, it may also be a substrate of other semiconductor materials, and the embodiments of the present disclosure are not limited thereto.

In some embodiments, when the type of transistors in the semiconductor structure is different, the arrangement of the semiconductor substrate is correspondingly different. In an embodiment, when the transistors are fin field effect transistors (FinFETs) or planar transistors, the semiconductor substrate may have a single-layer structure, i.e., a substrate made of one semiconductor material; when the transistors are gate-all-around field effect transistors (GAAFETs), the semiconductor substrate may have a stacked structure, i.e., a stack in which a silicon material and a silicon germanium material are disposed in a stack.

In some embodiments, when the transistors in the semiconductor structure are fin field effect transistors, the above step S101 may include: the semiconductor substrate is etched to form a plurality of fin structures; where the upper half part of the fin structure is the first active structure, and the lower half part of the fin structure is the second active structure. In other embodiments, when the transistors in the semiconductor structure are gate-all-around field effect transistors, the above step S101 may include: the semiconductor substrate is etched to form a columnar structure, where the semiconductor substrate is formed of silicon layers and silicon-germanium layers which are disposed alternately; the upper half part of the columnar structure is the first active structure, and the lower half part of the columnar structure is the second active structure. In still other embodiments, when the transistors in the semiconductor structure are planar transistors, the above step S101 may include: the semiconductor substrate is etched to form a bulk structure; where the upper half part of the block structure is the first active structure, and the lower half part of the block structure is the second active structure.

In the embodiments of the present disclosure, since the semiconductor structure includes two transistors (i.e., the first transistor and the second transistor), and the first active structure of the first transistor and the second active structure of the second transistor are formed by the same etching process, a larger etch depth can be adopted when the semiconductor substrate is etched. In an example, the height of the fin structure (which may also be the columnar structure or the bulk structure) obtained through etching may be greater than 100 nm. In an embodiment, the height of the fin structure may be set according to the actual situation, and the embodiments of the present disclosure are not limited thereto.

In some embodiments, the above step S101 may include: the active structure is formed on the semiconductor substrate, where the active structure includes a device area and a field area which are arranged in the third direction; the first active structure located in the field area in the active structure is removed, where the second active structure in the field area is retained.

In some embodiments, the device area is used to form a first source/drain structure and a second source/drain structure. The active structure in the device area is retained, and the source/drain structures of the transistors may be formed based on the active structure in the device area.

In some embodiments, the field area may be used to isolate two transistor cells adjacent in the third direction. The first active structure in the field area of the active structure is removed, and the second active structure is retained. After the first active structure in the field area is removed, a semiconductor material may be deposited based on the location of the original first active structure, thereby forming an insulating interlayer dielectric layer. In an embodiment, the field area may be used to form the first interlayer dielectric layer after the first active structure therein is removed.

In some embodiments, after the active structure is formed, the above method may further include: an oxide is deposited on the semiconductor substrate to form a shallow trench isolation (STI) structure. In the embodiments of the present disclosure, the oxide forming the shallow trench isolation structure may be silicon nitride (SiN, Si₃N₄), silicon dioxide (SiO₂), silicon oxycarbide (SiCO), or the like.

In some embodiments, after the shallow trench isolation structure is formed, the above method may further include: a chemical-mechanical planarization (CMP) process is performed on the shallow trench isolation structure. In the embodiments of the present disclosure, the chemical-mechanical planarization process performed on the shallow trench isolation structure enables that when the shallow trench isolation structure is subsequently etched, the shallow trench isolation structures in different areas correspond to the same etch depth, so that the exposed active structures have the same top height.

In some embodiments, after the shallow trench isolation structure is formed, the above method may further include: a portion of the shallow trench isolation structure is removed by etching to expose the first active structure. In an embodiment, in order to perform subsequent preparation of the first transistor (e.g., preparation the first source/drain structure) on the first active structure, the upper half portion of the shallow trench isolation structure may be etched first, so that the first active structure is exposed for subsequent preparation flow. At this time, the shallow trench isolation structure surrounds the second active structure, and the first active structure is exposed outside the shallow trench isolation structure.

In an embodiment, the etching process mentioned in the embodiments of the present disclosure may include any one of the followings: dry etching, wet etching, reactive ion etching (RIE), and chemical oxide removal (COR) process, and the embodiments of the present disclosure is not limited thereto.

In the embodiments of the present disclosure, the solvent used for etching the shallow trench isolation structure may be: DHF (including hydrofluoric acid (HF), hydrogen peroxide (H₂O₂) and water (H₂O)) solution or buffered oxide etch (BOE) solution. The solvent used in the etching treatment of the embodiments of the present disclosure may be selected according to the actual situation, and is not limited to the above-described solution.

In some embodiments, after the first active structure is exposed, ion implantation may be performed at the connection of the first active structure and the second active structure to form an electrical isolation layer, which is used for electrically isolating the first active structure from the second active structure.

In an embodiment, the ion in the ion-implantation includes P-type ion, N-type ion, or oxygen ion. The P-type ion may be boron, gallium, aluminum, and the like. The N-type ion may be phosphorus, arsenic, antimony, and the like.

In step S102, the first transistor is formed based on the first active structure.

In some embodiments, based on the first active structure, the first transistor (i.e., the bottom transistor) in the semiconductor structure may be prepared through standard processes for semiconductor preparation. The first transistor may include a first source/drain structure, a first source/drain metal, and a first interlayer dielectric layer. The first source/drain metal is electrically connected to the first source/drain structure, and the first interlayer dielectric layer is used to isolate the first source/drain structure from other structures. In an embodiment, the first interlayer dielectric layer may surround the first source/drain structure.

In an embodiment, the semiconductor material forming the first interlayer dielectric layer may be an insulating material.

In an embodiment, the first transistor may further include a first gate structure.

The first source/drain structure mentioned in the embodiments of the present disclosure is an abbreviation, and specifically refers to a first source structure and/or a first drain structure. In addition, the second source/drain structure, the first source/drain metal, the second source/drain metal, the source/drain groove and the like are all similar to the first source/drain structure, and “source/drain” is an abbreviation of “source and/or drain”.

In some embodiments, the above step S102 includes: the first source/drain structure is formed based on the first active structure; a semiconductor material is deposited on the first active structure and the first source/drain structure to form the first interlayer dielectric layer; after the first interlayer dielectric layer is formed, the first source/drain metal is formed.

In some embodiments, a groove or a via is formed in the first interlayer dielectric layer, and the groove or the via is metallized to form the first source/drain metal. In an embodiment, the metallization of the groove or via may include: a metallic material is deposited within the groove or via.

In an embodiment, after the first active structure is exposed, a source/drain groove of the first transistor may be formed based on the first active structure. Epitaxial growth of source/drain is performed within the source/drain groove of the first transistor, to obtain the first source/drain structure. A semiconductor material is deposed on the first active structure and the first source/drain structure to form the first interlayer dielectric layer. After the first interlayer dielectric layer is formed, a metallic material may be deposited on the first source/drain metal to form the first source/drain metal.

In some embodiments, the above step S102 further includes: a first dummy gate structure is formed in the gate area of the first transistor. In an embodiment, the formation of the first dummy gate structure may include: a semiconductor material (e.g., polysilicon) is deposited in the gate area of the first transistor to form the first dummy gate structure of the first transistor. In an embodiment, a gate area of the first transistor refers to an area for forming a gate structure, and a source/drain area of the first transistor refers to an area for forming a source/drain structure. In the third direction, gate areas and source/drain areas of the first transistor are alternately arranged.

In some embodiment, after the first dummy gate structure is formed, a first dummy gate sidewall may be formed on the side wall of the first dummy gate structure. In some embodiments, after the first dummy gate structure is removed, a gate material may be deposited at the location where the first dummy gate structure is removed, thereby forming the first gate structure of the first transistor.

In an embodiment, the material forming the dummy gate structure may be polysilicon, amorphous silicon, or the like; the material forming the dummy gate sidewall may be silicon oxide, silicon nitride, or the like. In an example, the first dummy gate sidewall 111 may have a single-layer structure, entirely made of the same material, such as porous carbon silicon oxyhydride (SiCOH).

In an embodiment, the first gate structure includes a first gate dielectric layer and a first gate electrode layer. The materials of the gate dielectric layer and the gate electrode layer may be set according to actual requirements, and the embodiments of the present disclosure are not limited thereto. In an embodiment, the first gate dielectric layer may be composed of a silicon oxide layer and a hafnium oxide layer having a high dielectric constant (K), and the thicknesses of the silicon oxide layer and the hafnium oxide layer may be determined according to the polarity and performance of the first transistor 11. In an embodiment, the first gate electrode layer may consist of a plurality of layers of electrode materials, each of which includes, but is not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In an example, the first gate dielectric layer may include a silicon oxide layer having a thickness of 0.6 nm and a hafnium oxide layer having a thickness of 1.7 nm.

In some embodiments, the formation of the first source/drain metal after the first interlayer dielectric layer is formed may include: the first interlayer dielectric layer is etched until the first source/drain structure is exposed to form a first groove; a metallic material is deposited within the first groove to form the first source/drain metal. In an embodiment, the first source/drain structure is electrically connected to the first source/drain metal.

In some embodiments, the formation of the first source/drain metal after the first interlayer dielectric layer is formed includes: the first interlayer dielectric layer is etched until the first source/drain structure is exposed to form a first groove; a metallic material is deposited within the first groove to form the first source/drain metal; a first metal interconnect layer is formed on the first source/drain metal.

In some embodiments, after the first source/drain metal is formed, standard back-end-of-line (BEOL) processes for preparing semiconductor (e.g., inter-interconnect-line dielectric deposition, metal line formation, lead-out pad formation, etc.) may be performed on the first source/drain metal to form the first metal interconnect layer.

In some embodiments, the above step S102 may include: the first source/drain structure is formed based on the first active structure; a semiconductor material is deposited on the first active structure and the first source/drain structure to form the first interlayer dielectric layer; after the first interlayer dielectric layer is formed, the first source/drain metal and a first interconnect via structure are formed.

In an embodiment, the first interconnect via structure at least partially passes through the first interlayer dielectric layer. In some embodiments, the depth of the first interconnect via structure may be equal to the depth of the first interlayer dielectric layer, and the first interconnect via structure completely passes through the first interlayer dielectric layer. In some embodiments, the depth of the first interconnect via structure may be less than the depth of the first interlayer dielectric layer, and the first interconnect via structure partially passes through the first interlayer dielectric layer.

In some embodiments, a groove or a via is formed in the first interlayer dielectric layer, and the groove or the via is metallized to form the first source/drain metal and the first interconnect via structure. In an embodiment, the metallization of the groove or via may include: a metallic material is deposited within the groove or via.

In some embodiments, one end of a third groove is communicated with the first groove. The formation of the first source/drain metal and the first interconnect via structure after the first interlayer dielectric layer is formed includes: the first interlayer dielectric layer is etched until the first source/drain structure is exposed to form the first groove; the first interlayer dielectric layer is etched to form the third groove; a metallic material is deposited within the first groove and the third groove to form the first source/drain metal and the first interconnect via structure, respectively. The first interconnect via structure formed in the third groove is electrically connected to the first source/drain metal formed in the first groove.

In some embodiments, the first groove and the third groove may be formed by the same etching process, or the first groove and the third groove may be formed by multiple etching processes, which are not limited by the present disclosure.

In some embodiments, the third groove is not in communication with the first groove. The formation of the first source/drain metal and the first interconnect via structure after the first interlayer dielectric layer is formed includes: the first interlayer dielectric layer is etched until the first source/drain structure is exposed to form the first groove; the first interlayer dielectric layer is etched to form the third groove; a metallic material is deposited within the first groove and the third groove to form the first source/drain metal and the first interconnect via structure, respectively. The first metal interconnect layer is formed on the first source/drain metal. The first interconnect via structure formed in the third groove is electrically connected to the first source/drain metal formed in the first groove through the first metal interconnect layer.

In some embodiments, after the first source/drain metal and the first interconnect via structure are formed, standard BEOL processes for preparing semiconductor (e.g., inter-interconnect-line dielectric deposition, metal line formation, lead-out pad formation, etc.) may be performed on the first source/drain metal to form the first metal interconnect layer.

In some embodiments, when the active structure includes a device area and a field area which are arranged in the third direction, after the active structure is formed on the semiconductor substrate, the first active structure located in the field area in the active structure may be removed, and a second active structure in the field area may be retained. Then, the first source/drain structure is formed based on the first active structure in the device area. Then, a semiconductor material is deposited on the first active structure and the first source/drain structure in the device area, and the semiconductor material is deposited on the retained second active structure in the field area to form the first interlayer dielectric layer.

In an embodiment, the first interlayer dielectric layer is disposed within the source/drain area and the field area of the semiconductor structure. The thickness of the first interlayer dielectric layer in the field area is greater than the thickness of the first interlayer dielectric layer in the source/drain area.

In step S103, flipping is performed on the first transistor, and the semiconductor substrate is removed.

In some embodiments, the first transistor may be formed after the first metal interconnect layer is formed on the first source/drain metal. Then, flipping may be performed on the first transistor, so that the prepared first transistor is located at the bottom, and the second active structure used for preparing the second transistor may be located at the upper, so as to facilitate subsequent preparation of the second transistor.

In an embodiment, after the first metal interconnect layer is formed, the first transistor may be bonded to the carrier wafer. In an embodiment, an insulating material (e.g., silicon oxide) may be deposited on the first metal interconnect layer to form an insulating layer, and the insulating layer is bonded to the carrier wafer. Flipping is performed then, after which the first transistor is located at the bottom of the semiconductor structure to form the bottom transistor of the semiconductor structure.

In some embodiments, the carrier wafer after bounding may provide physical support for the overturned first transistor after flipping, effectively preventing the first transistor from being broken by external force during the preparation of the second transistor.

In an embodiment, after flipping, the semiconductor substrate may be removed using a polishing process or a chemical-mechanical planarization process, exposing the second active structure.

In some embodiments, when the active structure includes a device area and a field area which are arranged in the third direction, the first interlayer dielectric layer may be formed on the retained second active structure in the field area during the preparation of the first transistor. After flipping, the semiconductor substrate is removed to expose the second active structure. Then, the second active structure located in the field area in the active structure may be removed to expose the first interlayer dielectric layer, so that a second source/drain structure may be formed subsequently based on the preparation of the second active structure in the device area.

In step S104, the second transistor is formed based on the second active structure. The second transistor includes a second source/drain structure, a second source/drain metal, and a second interlayer dielectric layer.

In some embodiments, based on the second active structure, the second transistor (i.e., the top transistor) in the semiconductor structure may be prepared through standard processes for semiconductor preparation. The second transistor may include a second source/drain structure, a second source/drain metal, and a second interlayer dielectric layer. The second source/drain metal is electrically connected to the second source/drain structure, and the second interlayer dielectric layer is used to isolate the second source/drain structure from other structures. In an embodiment, the second interlayer dielectric layer may surround the second source/drain structure.

In an embodiment, the semiconductor material forming the second interlayer dielectric layer may be an insulating material.

In an embodiment, the second transistor may further include a second gate structure.

In an embodiment, the semiconductor structure further includes an interconnect via structure. The first source/drain metal is communicated with the second source/drain metal through the interconnect via structure, the interconnect via structure passes through the first interlayer dielectric layer and the second interlayer dielectric layer.

In some embodiments, the above step S104 includes: the shallow trench isolation structure is thinned to expose the second active structure surrounded by the shallow trench isolation structure.

In some embodiments, the above step S104 includes: the second source/drain structure is formed based on the second active structure; a semiconductor material is deposited on the second active structure and the second source/drain structure to form the second interlayer dielectric layer; after the second interlayer dielectric layer is formed, the second source/drain metal is formed; the second interlayer dielectric layer and the first interlayer dielectric layer are etched in turn to form the first groove; a metallic material is deposited within the first groove to form an interconnect via structure.

In an embodiment, the first interlayer dielectric layer and the second interlayer dielectric layer may be deposited in a stack.

In some embodiments, a groove or a via is formed in the second interlayer dielectric layer, and the groove or the via is metallized to form the second source/drain metal.

In an embodiment, after the second active structure is exposed, a source/drain groove of the second transistor may be formed based on the second active structure. Epitaxial growth of source/drain is performed within the source/drain groove of the second transistor, to obtain the second source/drain structure. A semiconductor material is deposed on the second active structure and the second source/drain structure to form the second interlayer dielectric layer. After the first interlayer dielectric layer is formed, a metallic material may be deposited on the first source/drain metal to form the second source/drain metal. A first deep groove may be formed after the second source/drain metal, and a metallic material may be deposited within the first deep groove to form an interconnect via structure.

In an embodiment, the same etching process may be used to form the first deep groove and the groove required for the first source/drain metal in the interlayer dielectric layer, and the same metallic material deposition process may be used to simultaneously form the first source/drain metal and the interconnect via structure.

In some embodiments, the above step S104 further includes: a second dummy gate structure is formed in the gate area of the second transistor. In an embodiment, the formation of the second dummy gate structure may include: a semiconductor material (e.g., polysilicon) is deposited in the gate area of the second transistor to form the second dummy gate structure of the second transistor. In an embodiment, a gate area of the second transistor refers to an area for forming a gate structure, and a source/drain area of the second transistor refers to an area for forming a source/drain structure. In the third direction, gate areas and source/drain areas of the second transistor are alternately arranged.

In some embodiment, after the second dummy gate structure is formed, a second dummy gate sidewall may be formed on the side wall of the second dummy gate structure. In some embodiments, after the second dummy gate structure is removed, a gate material may be deposited at the location where the second dummy gate structure is removed, thereby forming the second gate structure of the second transistor.

In an embodiment, the second gate structure may be the same as the first gate structure or may be different from the first gate structure, and the embodiments of the present disclosure are not limited thereto.

In some embodiments, the formation of the second source/drain metal after the second interlayer dielectric layer is formed may include: the second interlayer dielectric layer is etched until the second source/drain structure is exposed to form a second groove; a metallic material is deposited within the second groove to form the second source/drain metal.

In some embodiments, one end of the first deep groove is communicated with the first groove, and the other end of the first deep groove is communicated with the second groove.

In an embodiment, a first end of the interconnect via structure is connected to the first source/drain metal, a second end of the interconnect via structure is connected to the second source/drain metal.

In some embodiments, the formation of the second source/drain metal after the second interlayer dielectric layer is formed includes: the second interlayer dielectric layer is etched until the second source/drain structure is exposed to form a second groove; a metallic material is deposited within the second groove to form the second source/drain metal; a second metal interconnect layer is formed on the second source/drain metal.

In some embodiments, after the second source/drain metal is formed, standard BEOL processes for preparing semiconductor (e.g., inter-interconnect-line dielectric deposition, metal line formation, lead-out pad formation, etc.) may be performed on the second source/drain metal to form the second metal interconnect layer.

In an embodiment, a first end of the interconnect via structure is connected to the first metal interconnect layer, a second end of the interconnect via structure is connected to the second metal interconnect layer.

In some embodiments, the first active structure is a first fin structure, the second active structure is a second fin structure; the etching of the second interlayer dielectric layer and the first interlayer dielectric layer in turn to form the first deep groove further includes: at least one fin in the second fin structure is removed; the second interlayer dielectric layer, the first interlayer dielectric layer, and a fin in the first fin structure corresponding to the at least one fin in the second fin structure are etched in turn until the first source/drain structure is exposed to form the first deep groove.

In an embodiment, all of the second fin structures are arranged in a second direction, and the second direction is perpendicular to the first direction.

In an embodiment, the removal of at least one fin in the second fin structure includes: at least one fin is removed using a fin-cutting process. In an embodiment, the second interlayer dielectric layer may be formed through deposition at the location of the at least one fin that has been removed.

In some embodiments, the first active structure is a first fin structure, the second active structure is a second fin structure; the above etching of the second interlayer dielectric layer and the first interlayer dielectric layer in turn to form the first deep groove includes: the second interlayer dielectric layer, at least one fin in the second fin structure, the first interlayer dielectric layer, and a fin in the first fin structure corresponding to the at least one fin in the second fin structure are etched in turn until the first source/drain structure is exposed to form the first deep groove.

In some embodiments, the etching of the second interlayer dielectric layer, the first interlayer dielectric layer, and the fin in the first fin structure corresponding to at least one fin in the second fin structure in turn until the first source/drain structure is exposed to form the first deep groove includes: the second interlayer dielectric layer, the first interlayer dielectric layer, a fin in the first fin structure corresponding to at least one fin in the second fin structure, and the first source/drain structure are etched in turn until the first source/drain metal is exposed to form the first deep groove.

In some embodiments, the etching of the second interlayer dielectric layer, at least one fin in the second fin structure, the first interlayer dielectric layer, and a fin in the first fin structure corresponding to at least one fin in the second fin structure until the first source/drain structure is exposed to form the first deep groove may include: the second interlayer dielectric layer, at least one fin in the second fin structure, the first interlayer dielectric layer, the fin in the first fin structure corresponding to the at least one fin in the second fin structure, and the first source/drain structure are etched in turn until the first source/drain metal is exposed to form the first deep groove.

In some embodiments, the first active structure is a first nanosheet and/or nanowire structure, the second active structure is a second nanosheet and/or nanowire structure; the above etching of the second interlayer dielectric layer and the first interlayer dielectric layer in turn to form the first deep groove further includes: the second interlayer dielectric layer, the first interlayer dielectric layer, and the first nanosheet and/or nanowire structure are etched in turn to form the first deep groove.

In some embodiments, the etching of the second interlayer dielectric layer and the first interlayer dielectric layer to form the first deep groove includes: a gate cutting process is performed on the first gate structure of the first transistor and the second gate structure of the second transistor to form a gate cut-off structure; the first interlayer dielectric layer of the first transistor and the second interlayer dielectric layer of the second transistor are lithographed based on the lithographic area which is self-aligned to the gate cutting structure to form the first deep groove.

In an embodiment, through the gate cutting process performed on the first gate structure of the first transistor and the second gate structure of the second transistor, both ends of the first gate structure and the second gate structure may be cut off, and both ends of the interlayer dielectric layer in the source/drain area may be cut off. Both ends of the first gate structure and the second gate structure refer to both ends of the gate structure in the second direction. Both ends of the interlayer dielectric layer refer to both ends of the interlayer dielectric layer in the second direction. Meanwhile, an insulating material may be deposited at both ends of the gate structure in the second direction and at both ends of the interlayer dielectric layer in the second direction to form the gate cut-off structure.

In an embodiment, the first interlayer dielectric layer and the second interlayer dielectric layer (i.e., the portion of the semiconductor structure corresponding to the lithographic area) are lithographed to form the first deep groove that is self-aligned against the edge of the gate cut-off structure. Further, because of the selectivity of the etching, the etching stops at the surface of the first source/drain metal; the gate cut-off structure, the second source/drain structure, and the first source/drain structure are not etched.

In some embodiments, the above step S104 may include: the second source/drain structure is formed based on the second active structure; a semiconductor material is deposited on the second active structure and the second source/drain structure to form the second interlayer dielectric layer; the first interlayer dielectric layer and the second interlayer dielectric layer are disposed in a stack; after the second interlayer dielectric layer is formed, the second source/drain metal and a second interconnect via structure are formed.

In an embodiment, the first interconnect via structure is communicated with the second interconnect via structure. The first interconnect via structure and the second interconnect via structure in combination form an interconnect via structure. In some embodiments, when the depth of the first interconnect via structure may be less than the depth of the first interlayer dielectric layer, the depth of the second interconnect via structure may be greater than the depth of the second interlayer dielectric layer; the second interconnect via structure completely passes through the second interlayer dielectric layer and partially passes through the first interlayer dielectric layer. In some embodiments, when the depth of the first interconnect via structure may be equal to the depth of the first interlayer dielectric layer, the depth of the second interconnect via structure may be equal to the depth of the second interlayer dielectric layer.

In some embodiments, a groove or a via is formed in the second interlayer dielectric layer, and the groove or the via is metallized to form the second source/drain metal and the second interconnect via structure.

In some embodiments, one end of a fourth groove is communicated with the second groove. The formation of the second source/drain metal and the second interconnect via structure after the second interlayer dielectric layer is formed includes: the first interlayer dielectric layer is etched until the second source/drain structure is exposed to form the second groove; the second interlayer dielectric layer is etched until the first interconnect via structure is exposed to form the fourth groove; a metallic material is deposited within the second groove and the fourth groove to form the second source/drain metal and the second interconnect via structure, respectively. The second interconnect via structure formed in the fourth groove is electrically connected to the second source/drain metal formed in the second groove.

In some embodiments, one end of the fourth groove is communicated with the second groove, and the other end of the fourth groove is communicated with the third groove. In some embodiments, the fourth groove and the second groove may be formed by the same etching process, or the fourth groove and the second groove may be formed by multiple etching processes, which are not limited by the present disclosure.

In some embodiments, the fourth groove is not in communication with the second groove. The formation of the second source/drain metal and the second interconnect via structure after the second interlayer dielectric layer is formed includes: the second interlayer dielectric layer is etched until the second source/drain structure is exposed to form the second groove; the first interlayer dielectric layer is etched to form the third groove; a metallic material is deposited within the first groove and the third groove to form the first source/drain metal and the first interconnect via structure, respectively; a second metal interconnect layer is formed on the second source/drain metal. The second interconnect via structure formed in the fourth groove is electrically connected to the second source/drain metal formed in the second groove through the second metal interconnect layer.

In some embodiments, a first end of the first interconnect via structure is connected to the first metal interconnect layer, a second end of the first interconnect via structure is connected to a first end of the second interconnect via structure, a second end of the second interconnect via structure is connected to the second metal interconnect layer.

In some embodiments, when the active structure includes a device area and a field area which are arranged in the third direction, the first interlayer dielectric layer may be formed on the retained second active structure in the field area during the preparation of the first transistor. After flipping, the semiconductor substrate is removed to expose the second active structure. Then, the second active structure located in the field area in the active structure may be removed to expose the first interlayer dielectric layer, so that a second source/drain structure may be formed subsequently based on the preparation of the second active structure in the device area. Then, the second source/drain structure is formed based on the second active structure in the device area. Then, a semiconductor material is deposited on the second active structure and the second source/drain structure in the device area, and the semiconductor material is deposited on the exposed second interlayer dielectric layer in the field area to form the second interlayer dielectric layer.

In an embodiment, the second interlayer dielectric layer is disposed within the source/drain area and the field area of the semiconductor structure. The second active structure is absent within the field area, such that the thickness of the second interlayer dielectric layer in the field area is greater than the thickness of the second interlayer dielectric layer in the source/drain area. In an embodiment, the interconnect via structure passes through the first interlayer dielectric layer and the second interlayer dielectric layer in the field area.

In an embodiment, the second interlayer dielectric layer and the first interlayer dielectric layer in the field area are disposed in a stack, and the second interlayer dielectric layer and the first interlayer dielectric layer are in contact with each other.

In some embodiments, the second metal interconnect layer includes: a first interconnect sublayer and a second interconnect sublayer; the first interconnect sublayer is in direct contact with the second source/drain metal and the second interconnect via structure, and can also be understood as M0 metal; the second interconnect sublayer is in direct contact with the second interconnect sublayer and can also be understood as M1 metal.

In an embodiment, the location of the interconnect via structure may be set according to the actual situation, and the embodiments of the present disclosure are not limited thereto. In an embodiment, the interconnect via structure may be located outside the field area of the semiconductor structure. In an embodiment, the interconnect via structure may be located in the source/drain area of the semiconductor structure.

In an embodiment, when the interconnect via structure is located in the source/drain area of the semiconductor structure, the interconnect via structure is located on one side of the active structure in the second direction; or, interconnect via structures are located on both sides of the active structure; or, the interconnect via structure is located in the middle of the active structure.

In an embodiment, when the interconnect via structure is located in the field area of the semiconductor structure, the interconnect via structure is located on one side of the active structure in the second direction; or, interconnect via structures are located on both sides of the active structure; or, the interconnect via structure is located in the middle of the active structure; in the third direction, the interconnect via structure is located on one side of the active structure; or, interconnect via structures are located on both sides of the active structure.

In some embodiments, after the interconnect via structure and the second metal interconnect layer are formed, the second transistor may be prepared, thus completing the preparation of the semiconductor structure in the embodiments of the present disclosure.

In the embodiments of the present disclosure, the first transistor is formed based on the first portion of the active structure, and after clipping, the second transistor is formed based on the second portion of the active structure. In this way, the first transistor and the second transistor are disposed opposite to each other, and the first source/drain metal of the first transistor is communicated with the second source/drain metal of the second transistor through an interconnect via structure, the interconnect via structure passes through the first interlayer dielectric layer of the first transistor and the second interlayer dielectric layer of the second transistor. Thus, in the case where the first transistor and the second transistor are self-aligned, source/drain interconnection between the first transistor and the second transistor is achieved.

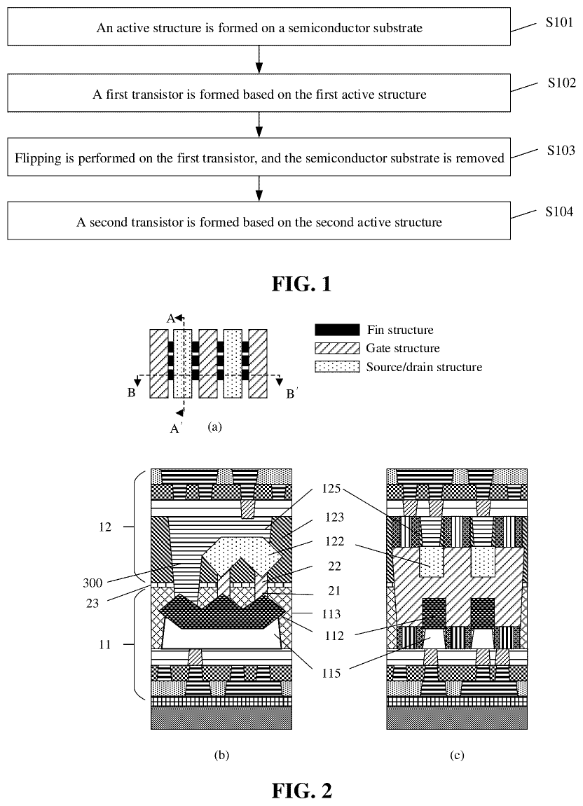

FIG. 2 is a schematic structural diagram of a semiconductor structure according to an embodiment of the present disclosure. In FIG. 2, (a) is a top view of the semiconductor structure. For ease of understanding, only the fin structure, the gate structure, and the source/drain structure are shown in this top view; (b) is a cross-section view of the semiconductor structure taken along a cross-section of the source/drain structure (i.e., the A-A′ direction); (c) is a cross-section view of the semiconductor structure taken as a cross-section of the fin structure (i.e., the B-B′ direction).

Referring to (a) to (c) of FIG. 2, the first active structure 21 in the first transistor 11 and the second active structure 22 in the second transistor 14 are fin structures. The first active structure 21 and the second active structure 22 are one active structure formed by the same process, and a first portion of the active structure is used as the first active structure 21 in the first transistor 11, while a second portion of the active structure is used as the second active structure 22 in the second transistor 14.

Referring to (b) and (c) in FIG. 2, the first source/drain structure 112 (i.e., the source/drain structure of the first transistor 11) corresponding to the first active structure 21 of the first transistor 11 and the second source/drain metal 125 corresponding to the second active structure 22 of the second transistor 12 are interconnected by an interconnect via structure 300.

Referring to (2) in FIG. 2, the first source/drain structure 112 of the first transistor 11 and the second source/drain structure 122 of the second transistor 12 are disposed opposite to each other.

Here, the preparation process of the semiconductor structure shown in FIG. 2 will be described in conjunction with the above-described preparation method.

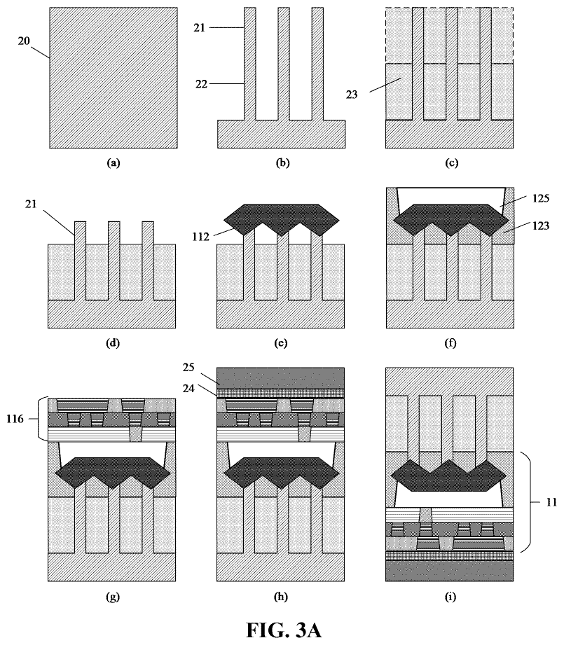

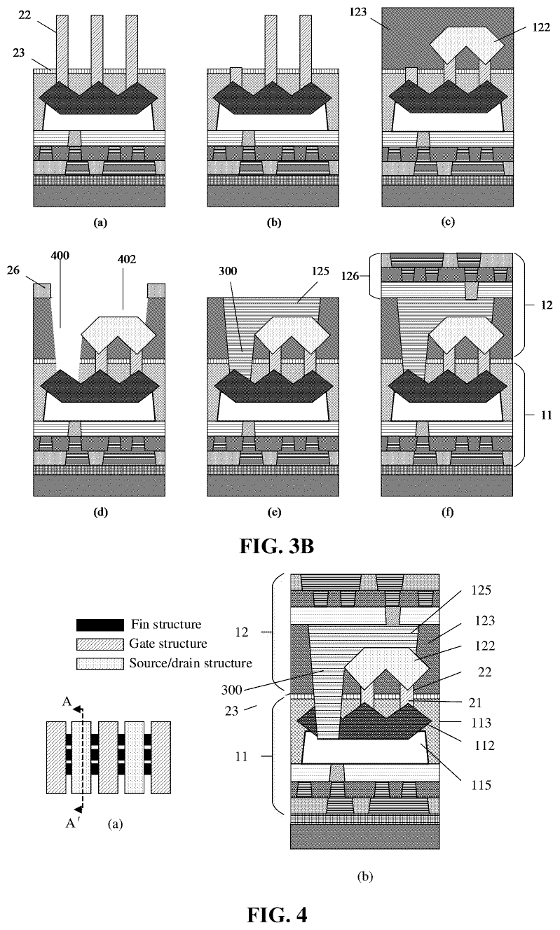

FIG. 3A and FIG. 3B are schematic diagrams of a preparation process of the semiconductor structure in FIG. 2 according to an embodiment of the present disclosure. FIGS. 3A and 3B are cross-section views of the semiconductor structure taken along the cross-section of the source/drain structure (i.e., the A-A′ direction).

First step: a semiconductor substrate 20 (see (a) in FIG. 3A) is provided, and a plurality of active structures is formed on the semiconductor substrate 20 by etching the semiconductor substrate 20, the active structures including a first active structure 21 and a second active structure 22 (see (b) in FIG. 3A). In the embodiments of the present disclosure, the active structures are fin structures, the first active structure 21 is a first fin structure, and the second active structure 22 is a second fin structure.

In an embodiment, the semiconductor substrate 20 is anisotropically etched to form a plurality of active structures extending in the same direction, and the height of the active structures may be greater than 100 nm. The semiconductor substrate 20 may be a silicon substrate or a silicon-on-insulator (SOI) substrate, and the material of the silicon substrate may include, but is not limited to, at least one of the following: silicon, silicon germanium, silicon carbide germanium, and silicon carbide.

Second step: an isolation structure is formed at the recesses between the active structures and on both sides of the plurality of active structures, and a first portion (i.e., the first active structure 21) of the plurality of active structures is exposed (see (c) in FIG. 3A).

In an embodiment, oxide is deposited at recesses between the plurality of active structures and on both sides of the plurality of active structures to form a shallow trench isolation structure 23, and the shallow trench isolation structure 23 is planarized. Thereafter, the first portion of the shallow trench isolation structure 23 is etched such that the first part of the plurality of active structures is exposed.

Third step: the first active structure 21 is etched to form a trench at the source/drain location (see (d) in FIG. 3A).

In an embodiment, the height of the first active structure 21, after being etched, at the source/drain location that is smaller than at the gate location, so that a trench can be formed at the source/drain location.

In some embodiments, a first dummy gate structure (not shown) of the first transistor 11 may be formed prior to the formation of the source/drain groove.

Fourth step: epitaxial growth is performed on the first active structure 21 to form the first source/drain structure 112, a semiconductor material is deposited on the peripheral side of the first source/drain structure 112 to form a first interlayer dielectric layer 113, a metallic material is deposited on the first source/drain structure 112 to form a first source/drain metal 124, and a first metal interconnect layer 116 of the first transistor 11 by the BEOL process (see (e), (f) and (g) in FIG. 3A).

Fifth step: an insulating layer 24, the material of which may be silicon oxide, is deposited on the first transistor 11, a carrier wafer 25 is bonded to the first transistor 11 (see (h) in FIG. 3A) from the above of the insulating layer 24, and then flipping is performed on the carrier wafer 25 with the first transistor 21 formed (see (i) in FIG. 3A).

Here, the carrier wafer 25 after bounding may provide physical support for the overturned first transistor 11 after flipping, effectively preventing the first transistor 11 from being damaged by external force during the preparation of the second transistor 12.

Sixth step: the semiconductor substrate 20 is removed and the second portion of the shallow trench isolation structure 23 is etched, so that the second portion (i.e., the second active structure 22) of the plurality of active structures is exposed (see (a) in FIG. 3B).

In an embodiment, after the first transistor 11 is flipped, the semiconductor substrate 20 is placed upward, and a portion of the semiconductor substrate 20 is removed by wafer thinning until the shallow trench isolation structure 23 and the edge portions of the plurality of second active structures 22 are exposed, and then the second portion of the shallow trench isolation structure 23 is etched. In an embodiment, during etching of the second portion of the shallow trench isolation structure 23, a certain thickness may be retained to function to isolate the first transistor 11 from the second transistor 12. The thickness of the retained shallow trench isolation structure 23 may be set according to specific situation, and the embodiments of the present disclosure are not limited thereto. After the second portion of the shallow trench isolation structure 23 is etched away, the second active structure 22 is also exposed.

Seventh step: one second active structure 22 of the plurality of second active structures 22 is removed (see (b) in FIG. 3B).

In an embodiment, one of the second active structures 22 may be cut off through fin cut. The fin cut can be achieved physically or chemically. In an embodiment, one second active structure 22 may be cut off, or a plurality of second active structures 22 may be cut off, and the embodiments of the present disclosure are not limited to this.

In an embodiment, one second active structure 22 of the plurality of second active structures 22 may not be removed, and the second active structure 22 to be removed may be directly etched away in a subsequent etching process for forming the first deep groove.

Eighth step: epitaxial growth is performed on the second active structure 22 to form a second source/drain structure 122, and a semiconductor material is deposited to form a second interlayer dielectric layer 123 (see (c) in FIG. 3B).

In an embodiment, epitaxial growth may be performed on second source/drain structures 122 other than the cut-off second source/drain structure 122 to form the second source/drain structures 122.

In an embodiment, as shown in the drawings, the first interlayer dielectric layer 113, the shallow trench isolation structure 23, and the second interlayer dielectric layer 123 at this time isolate the source/drain structures of the upper transistor from the source/drain structures of the lower transistor.

Ninth step: a photoresist 26 is deposited on the second interlayer dielectric layer 123, and the second interlayer dielectric layer 123, the shallow trench isolation structure 23, and the first interlayer dielectric layer 113 are etched in a certain area (see (d) in FIG. 3B).

In an embodiment, a layer of photoresist 26 is deposited on the second interlayer dielectric layer 123; thereafter, the photoresist 26 is exposed using a mask and is dissolved in the area where the trench is to be formed; next, the second interlayer dielectric layer 123, the shallow trench isolation structure 23, and the first interlayer dielectric layer 113 are etched in the area that are not masked by the photoresist 26 to form the first deep groove 400 and the second groove 402.

In an embodiment, because of the blocking of the second source/drain structure 122, the second interlayer dielectric layer 123, the shallow trench isolation structure 23, and the first interlayer dielectric layer 113 located below the second source/drain structure 122 are not etched. In this way, the first deep groove 400 passing through the first interlayer dielectric layer 113 and the second interlayer dielectric layer 123 may be formed at the location of the removed second active structure 22, thereby exposing the first source/drain structure 112 of the first transistor 11. At the same time, the second groove 402 passing through the second interlayer dielectric layer 123 on the second source/drain structure 122 may also be formed, thereby exposing the second source/drain structure 122 of the second transistor 12.

In an embodiment, one end of the first deep groove 400 obtained by the above etching is communicated with the second groove 402.

In an embodiment, if one of the second active structures 22 among the plurality of second active structures 22 is not removed in the seventh step, the active structure in the corresponding area of the first deep groove 400 may be etched in this step to form the first deep groove 400.

Tenth step: a metallic material is deposited in the first deep groove 400 and the second groove 402 (see (e) in FIG. 3B).

In an embodiment, when the metallic material is deposited in the first deep groove 400 and the second groove 402, the metallic material is deposited in the first deep groove 400 on the one hand to implement the interconnect via structure 300 and in the second groove 402 on the other hand to implement the second source/drain metal 125. Since one end of the first deep groove 400 is communicated with the second groove 402, and the other end exposes the first source/drain metal 115, the interconnect via structure 300 implements the interconnection between the first source/drain metal 115 and the second source/drain metal 125.

Eleventh step: the BEOL process of the second transistor 12 is completed to form the second metal interconnect layer 126 (see (f) in FIG. 3B).

FIG. 4 is a schematic structural diagram of a semiconductor structure according to an embodiment of the present disclosure. In FIG. 4, (a) is a top view of the semiconductor structure. For ease of understanding, only the fin structure, the gate structure, and the source/drain structure are shown in this top view; (b) is a cross-section view of the semiconductor structure taken along a cross-section of the source/drain structure (i.e., the A-A′ direction).

In an embodiment, the first active structure 21 in the first transistor 11 and the second active structure 22 in the second transistor 12 are fin structures. The semiconductor structure shown in FIG. 4 differs from the semiconductor structure shown in FIG. 2 in that: the interconnect via structure 300 further passes through the first source/drain structure 112 to expose the first source/drain metal 115. As such, the second source/drain metal 125 is interconnected not only with the first source/drain structure 112, but also with the first source/drain metal 115. The implementation of the interconnection between the first source/drain metal 115 and the second source/drain metal 125 further improves the electrical performance of the interconnection.

In order to prepare the semiconductor structure shown in FIG. 4, on the basis of the flow shown in FIGS. 3A and 3B, the first source/drain structure 112 may be etched in the process of etching in the ninth step, to obtain an interconnect via structure 300 which passes through the first interlayer dielectric layer 113, the second interlayer dielectric layer 123, and the first source/drain structure 112.

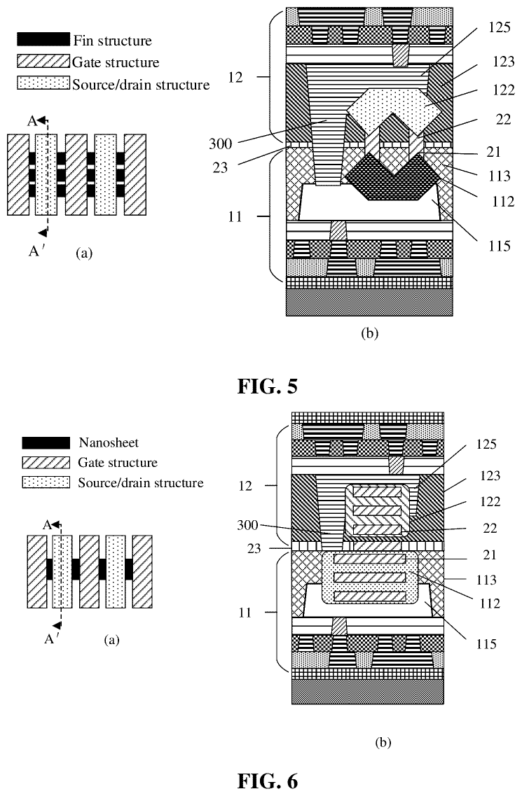

FIG. 5 is a schematic structural diagram of a semiconductor structure according to an embodiment of the present disclosure. In FIG. 5, (a) is a top view of the semiconductor structure. For ease of understanding, only the nanosheet structure, the gate structure, and the source/drain structure are shown in this top view; (b) is a cross-section view of the semiconductor structure taken along a cross-section of the source/drain structure (i.e., the A-A′ direction).

In an embodiment, the first active structure 21 in the first transistor 11 and the second active structure 22 in the second transistor 12 are fin structures. The first transistor 11 and the second transistor 12 are fin field effect transistors. The semiconductor structure shown in FIG. 5 is different from the semiconductor structure shown in FIGS. 2 and 4 in that: the interconnect via structure 300 is located outside the active area (including the first source/drain structure 112 and the second source/drain structure 122) and passes through the interlayer dielectric layer of the two transistors to expose the first source/drain metal 115. As such, the second source/drain metal 125 is interconnected only with the first source/drain metal 115. By setting the location of the interconnect via structure 300 outside the active area, it is not necessary to perform fin cut on the second active structure 22, thereby ensuring the performance matching between the first transistor 11 and the second transistor 12.

In order to prepare the semiconductor structure shown in FIG. 5, on the basis of the flow shown in FIGS. 3A and 3B, the seventh step may be skipped, the first source/drain metal 115 and the second source/drain metal 125 may be laterally extended in the fourth step of forming the first source/drain metal 115 and the ninth step of forming the second source/drain metal 125, so as to ensure enough space for manufacturing of the interconnect via structure 300.

FIG. 6 is a schematic structural diagram of a semiconductor structure according to an embodiment of the present disclosure. In FIG. 6, (a) is a top view of the semiconductor structure. For ease of understanding, only the nanosheet, the gate structure, and the source/drain structure are shown in this top view; (b) is a cross-section view of the semiconductor structure taken along a cross-section of the source/drain structure (i.e., the A-A′ direction).

Referring to (a) and (b) of FIG. 6, the first active structure 21 in the first transistor 11 and the second active structure 22 in the second transistor 12 are nanosheets. The first active structure 21 and the second active structure 22 are one active structure formed by the same process, and a first portion (i.e., one or more nanosheets) of the active structure is used as the first active structure 21 in the first transistor 11, while a second portion (i.e., one or more nanosheets) of the active structure is used as the second active structure 22 in the second transistor 12. The first transistor 11 and the second transistor 12 are gate-all-around field effect transistors.

Referring to (b) in FIG. 6, the first source/drain structure 112 (i.e., the source/drain structure of the first transistor 11) corresponding to the first active structure 21 of the first transistor 11 and the second source/drain metal 125 (i.e., the source/drain structure of the second transistor 12) corresponding to the second active structure 22 of the second transistor 12 are interconnected by an interconnect via structure 300.

As can be understood, the first source/drain structure 112 of the first transistor 11 and the second source/drain structure 122 of the second transistor 12 are disposed opposite to each other.

Here, the preparation process of the semiconductor structure shown in FIG. 6 will be described in conjunction with the above-described preparation method.

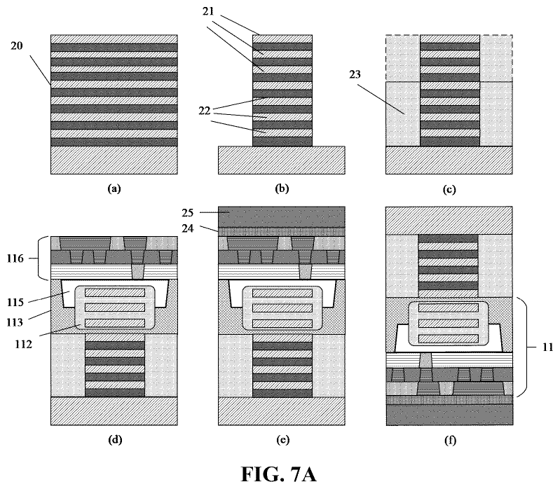

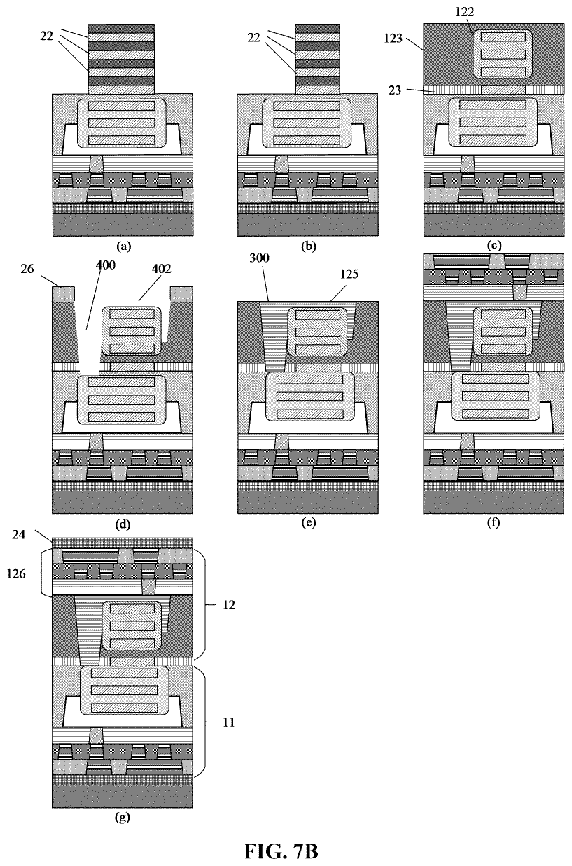

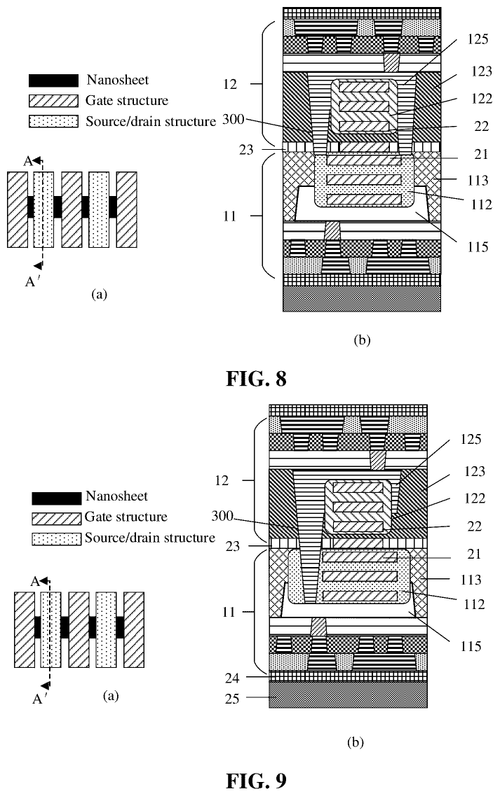

FIG. 7A and FIG. 7B are schematic diagrams of a preparation process of the semiconductor structure in FIG. 6 according to an embodiment of the present disclosure. FIGS. 7A and 7B are cross-section views of the semiconductor structure taken along the cross-section of the source/drain structure (i.e., the A-A′ direction).

First step: a semiconductor substrate 20 (see (a) in FIG. 7A) is provided, and an active structure (columnar structure) is formed on the semiconductor substrate 20 (see (b) in FIG. 7A).

In an embodiment, the semiconductor substrate 20 may be formed of two different semiconductor materials (i.e., a first semiconductor material and a second semiconductor material) stacked in turn, and the two semiconductor materials may be a combination of any two of the following materials: silicon, silicon germanium, silicon germanium carbon, and silicon carbide. The semiconductor substrate 20 is anisotropically etched to form the active structure extending in the vertical direction of the semiconductor substrate 20.

Second step: shallow trench isolation structures are formed by deposition on both sides of the active structure, and a first portion (including the first active structure 21) of the active structure is exposed (see (c) in FIG. 7A). The process of the second step may refer to the second step in the preparation process of the semiconductor structure shown in FIG. 3A.

Third step: a first source/drain structure 112 is formed around the first active structure 21, a first source/drain metal 115 is formed by deposition on the first source/drain structure 112, and a first transistor 11 is formed by subsequent processes (see (d) in FIG. 7A).

In an embodiment, a selective etching process method is adopted to remove the first semiconductor material of the active structure by etching, and the second semiconductor material which is not etched is distributed in a sheet shape, thereby forming a plurality of nanosheets (i.e., the first active structure 21) arranged in parallel in the first transistor 11; thereafter, epitaxial growth is performed around the plurality of first active structures 21 to form a first source/drain structure 112. Then, the deposition of the first interlayer dielectric layer 113 is completed; and after that, the BEOL process of the first transistor 11 is completed to form the first metal interconnect layer 116, and the fabrication of the first transistor 11 is completed.

Fourth step: an insulating layer 24, the material of which may be silicon oxide, is deposited on the first transistor 11, a carrier wafer 25 is bonded to the first transistor 11 (see (e) in FIG. 7A) from the above of the insulating layer 24, and then flipping is performed (see (f) in FIG. 7A).

Fifth step: the semiconductor substrate 20 is removed and the second portion of the shallow trench isolation structure 23 is etched, so that the second portion (i.e., the second active structure 22) of the active structure is exposed (see (a) in FIG. 7B).

Here, after the first transistor 11 is flipped, the semiconductor substrate 20 is placed upward, and a portion of the semiconductor substrate 20 is removed by wafer thinning until the shallow trench isolation structure 23 is exposed, and then the second portion of the shallow trench isolation structure 23 is etched. After the second portion of the shallow trench isolation structure 23 is etched away, the second active structure 22 is also exposed.

In an embodiment, during etching of the second portion of the shallow trench isolation structure 23, a certain thickness may be retained to function to isolate the first transistor 11 from the second transistor 12. The thickness of the retained shallow trench isolation structure 23 may be set according to specific situation, and the embodiments of the present disclosure are not limited thereto.

Sixth step: the second active structure 22 in the second transistor 12 is trimmed (see (b) in FIG. 7B), a second source/drain structure 122 is formed around the trimmed second active structure 22, and a semiconductor material is deposited to form a second interlayer dielectric layer 123 (see (c) in FIG. 7B).

In an embodiment, the width of the second active structure 22 in the second transistor 12 may be reduced by fin trimming, such that the width of the second active structure 22 in the second transistor 12 is smaller than the width of the first active structure 21 in the first transistor 11. The fin trimming can be achieved physically or chemically.

In an embodiment, the trimming of the second active structure 22 may be implemented by entirely trimming the second portion of the columnar structure (see (b) in FIG. 7B). In some cases, the trimming of the second active structure 22 may also be implemented by trimming only the nanosheets corresponding to the second active structure 22, and the embodiments of the present disclosure are not limited thereto.

In an embodiment, it can be seen from the drawings that, the first interlayer dielectric layer 113, the shallow trench isolation structure 23, and the second interlayer dielectric layer 123 at this time isolate the source/drain structures of the upper transistor from the source/drain structures of the lower transistor.

Seventh step: a photoresist 26 is deposited on the second interlayer dielectric layer 123, and the second interlayer dielectric layer 123, the shallow trench isolation structure 23, and the first interlayer dielectric layer 113 are etched in a certain area (see (d) in FIG. 7B).

In an embodiment, a layer of photoresist 26 is deposited on the second interlayer dielectric layer 123; thereafter, the photoresist 26 is exposed using a mask and is dissolved in the area where the trench is to be formed; next, the second interlayer dielectric layer 123, the shallow trench isolation structure 23, and the first interlayer dielectric layer 113 are etched in the area that are not masked by the photoresist 26 to form the first deep groove 400 and the second groove 402.

In an embodiment, because of the blocking of the second source/drain structure 122, the second interlayer dielectric layer 123, the shallow trench isolation structure 23, and the first interlayer dielectric layer 113 located below the second source/drain structure 122 are not etched. In this way, the first deep groove 400 passing through the first interlayer dielectric layer 113 and the second interlayer dielectric layer 123 may be formed at the location of the removed second active structure 22, thereby exposing the first source/drain structure 112 of the first transistor 11. At the same time, a second groove 402 is formed. In an embodiment, one end of the first deep groove 400 obtained by the above etching is communicated with the second groove 402.

Eighth step: a metallic material is deposited in the first deep groove 400 and the second groove 402 (see (e) in FIG. 7B).

In an embodiment, when the metallic material is deposited in the first deep groove 400 and the second groove 402, the metallic material is deposited in the first deep groove 400 on the one hand to implement the interconnect via structure 300 and in the second groove 402 on the other hand to implement the second source/drain metal 125. Since one end of the first deep groove 400 is communicated with the second groove 402, and the other end exposes the first source/drain metal 115, the interconnect via structure 300 implements the interconnection between the first source/drain metal 115 and the second source/drain metal 125.

Ninth step: the BEOL process of the second transistor 12 is completed to form the second metal interconnect layer 126 (see (f) in FIG. 7B), and an insulating layer 24 is deposited (see (g) in FIG. 7B).

FIG. 8 is a schematic structural diagram of a semiconductor structure according to an embodiment of the present disclosure. In FIG. 8, (a) is a top view of the semiconductor structure. For ease of understanding, only the nanosheet, the gate structure, and the source/drain structure are shown in this top view; (b) is a cross-section view of the semiconductor structure taken along a cross-section of the source/drain structure (i.e., the A-A′ direction).

In an embodiment, the first active structure 21 in the first transistor 11 and the second active structure 22 in the second transistor 12 are both nanosheets. The first transistor 11 and the second transistor 12 are gate-all-around field effect transistors. The semiconductor structure shown in FIG. 8 differs from the semiconductor structure shown in FIG. 6 in that: two interconnect via structures 300 are respectively located on both sides of the second source/drain structure 122 of the second transistor 12 to expose the first source/drain structure 112. As such, the interconnection between the first source/drain structure 112 and the second source/drain metal 125 is implemented through the two interconnect via structures 300, which further improves the electrical performance of the interconnection.

In order to prepare the semiconductor structure shown in FIG. 8, on the basis of the flow shown in FIGS. 7A and 7B, the second active structure 22 in the second transistor 12 may be trimmed at both ends in the sixth step to further reduce the width of the second active structure 22; and in the seventh step, the first interlayer dielectric layer 113 and the second interlayer dielectric layer 123 are etched on both sides of the second source/drain structure 122 to form two interconnect via structures 300.

FIG. 9 is a schematic structural diagram of a semiconductor structure according to an embodiment of the present disclosure. In FIG. 9, (a) is a top view of the semiconductor structure. For ease of understanding, only the nanosheet, the gate structure, and the source/drain structure are shown in this top view; (b) is a cross-section view of the semiconductor structure taken along a cross-section of the source/drain structure (i.e., the A-A′ direction).

In an embodiment, the first active structure 21 in the first transistor 11 and the second active structure 22 in the second transistor 12 are both nanosheets. The first transistor 11 and the second transistor 12 are gate-all-around field effect transistors. The semiconductor structure shown in FIG. 9 differs from the semiconductor structure shown in FIG. 6 in that: the interconnect via structure 300 further passes through the first source/drain structure 112 to expose the first source/drain metal 115. As such, the implementation of the interconnection between the first source/drain metal 115 and the second source/drain metal 125 further improves the electrical performance of the interconnection.

In order to prepare the semiconductor structure shown in FIG. 9, on the basis of the flow shown in FIGS. 7A and 7B, the first source/drain structure 112 may be etched in the seventh step, to obtain an interconnect via structure 300 which passes through the first interlayer dielectric layer 113, the second interlayer dielectric layer 123, and the first source/drain structure 112.

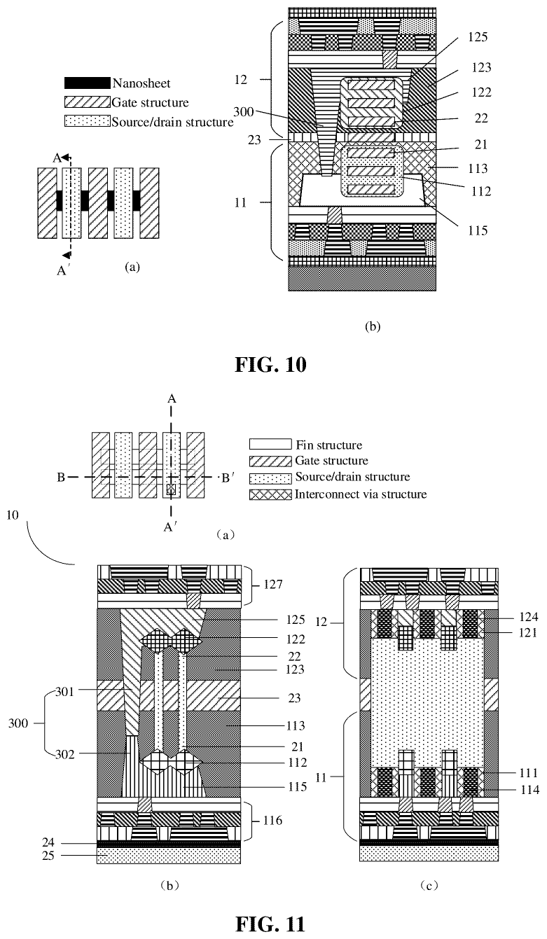

FIG. 10 is a schematic structural diagram of a semiconductor structure according to an embodiment of the present disclosure. In FIG. 10, (a) is a top view of the semiconductor structure. For ease of understanding, only the nanosheet, the gate structure, and the source/drain structure are shown in this top view; (b) is a cross-section view of the semiconductor structure taken along a cross-section of the source/drain structure (i.e., the A-A′ direction).

In an embodiment, the first active structure 21 in the first transistor 11 and the second active structure 22 in the second transistor 12 are nanosheets. The first transistor 11 and the second transistor 12 are gate-all-around field effect transistors. The semiconductor structure shown in FIG. 10 is different from the semiconductor structure shown in FIG. 6 in that: the interconnect via structure 300 is located outside the active area (including the first source/drain structure 112 and the second source/drain structure 122) and passes through a first interlayer dielectric layer 113 and a second interlayer dielectric layer 123 to expose the first source/drain metal 115. As such, the second source/drain metal 125 is interconnected only with the first source/drain metal 115. By setting the location of the interconnect via structure 300 outside the active area, it is not necessary to trim the nanosheets, thereby ensuring the performance matching between the first transistor 11 and the second transistor 12.

In order to prepare the semiconductor structure shown in FIG. 5, on the basis of the flow shown in FIGS. 3A and 3B, the sixth step may be skipped, the first source/drain metal 115 and the second source/drain metal 125 may be laterally extended in the third step of forming the first source/drain metal 115 and the eighth step of forming the second source/drain metal 125, so as to ensure enough space for manufacturing of the interconnect via structure 300.

FIG. 11 is a schematic structural diagram of a semiconductor structure according to an embodiment of the present disclosure. Here, in FIG. 11, (a) is a top view of the semiconductor structure. For ease of understanding, only the fin structure, the gate structure, and the source/drain structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

Referring to FIG. 11, the semiconductor structure 10 includes a first transistor 11 and a second transistor 12, and the active structure in the semiconductor structure 10 is a plurality of fin structures. The fin structure is divided into upper and lower parts, denoted as a first part and a second part, respectively, the first part serving as the first active structure 21 in the first transistor 11, and the second part serving as the second active structure 22 in the second transistor 12. The first source/drain metal 115 in the first transistor 11 and the second source/drain metal 125 in the second transistor 12 are communicate with each other through the interconnect via structure 13. A shallow trench isolation structure 23 is provided between the first transistor 11 and the second transistor 12, and the shallow trench isolation structure 23 is used to isolate the first transistor 11 and the second transistor 12.

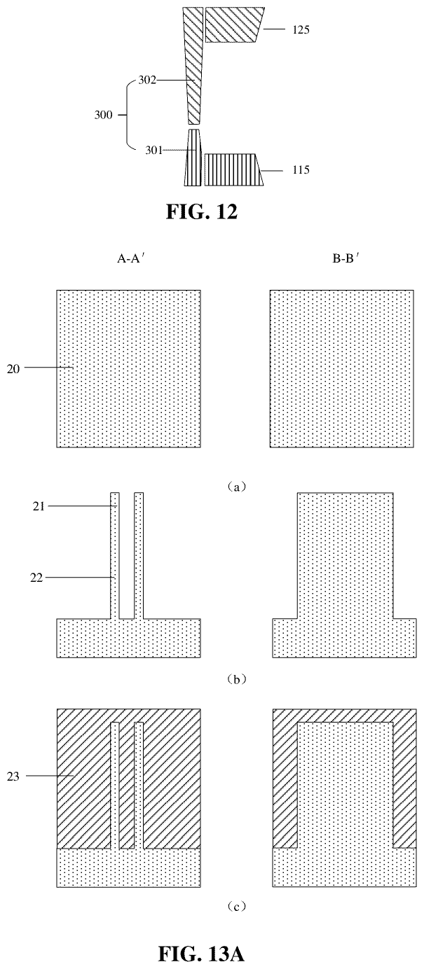

FIG. 12 is a schematic structural diagram of an interconnect via structure according to an embodiment of the present disclosure. FIG. 12 shows a schematic disassembly view of the interconnect hole structure 300, the first source/drain metal 115, and the second source/drain metal 125. Referring to FIG. 12, the interconnect via structure 300 may include two parts, one part is a first interconnect via structure 301, and the first interconnect via structure 301 is connected to the first source/drain metal 115; the other part is a second interconnect via structure 302, and the second interconnect via structure 302 is connected to the second source/drain metal 125; the first interconnect via structure 301 and the second interconnect via structure 302 are connected.

In an embodiment, the interconnect via structure 300 in FIG. 12 corresponds to the interconnect via structure 300 in the semiconductor structure shown in FIG. 11, and the interconnect via structure 300 in the embodiments of the present disclosure may be other structures.

In the embodiments of the present disclosure, the first active structure 21 of the first transistor 11 and the second active structure 22 of the second transistor 12 are formed by the same etching process, so that self-alignment of the first transistor 11 and the second transistor 12 can be realized.

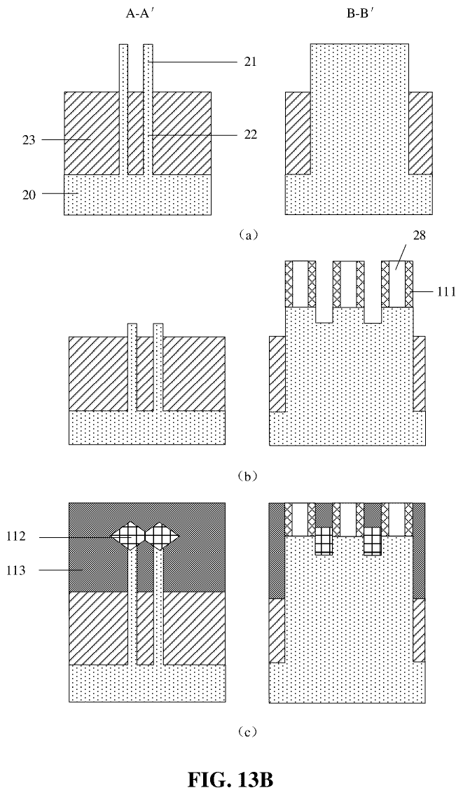

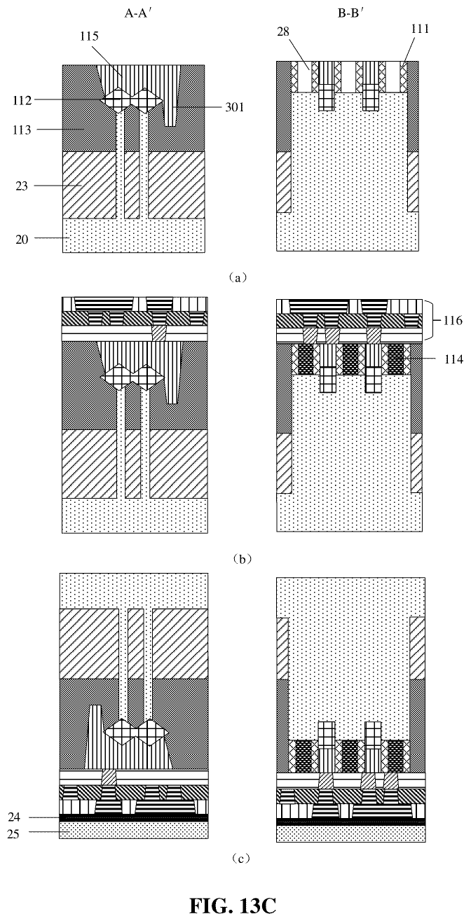

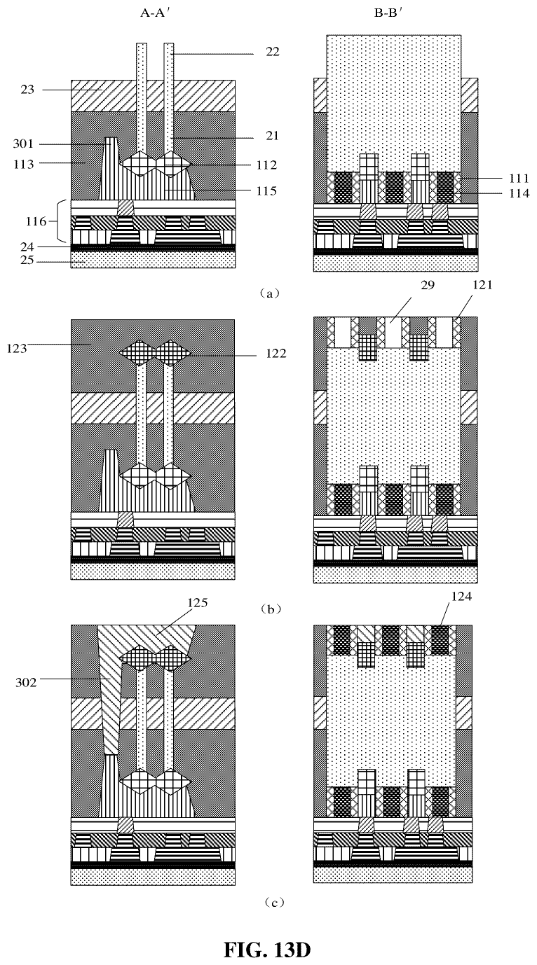

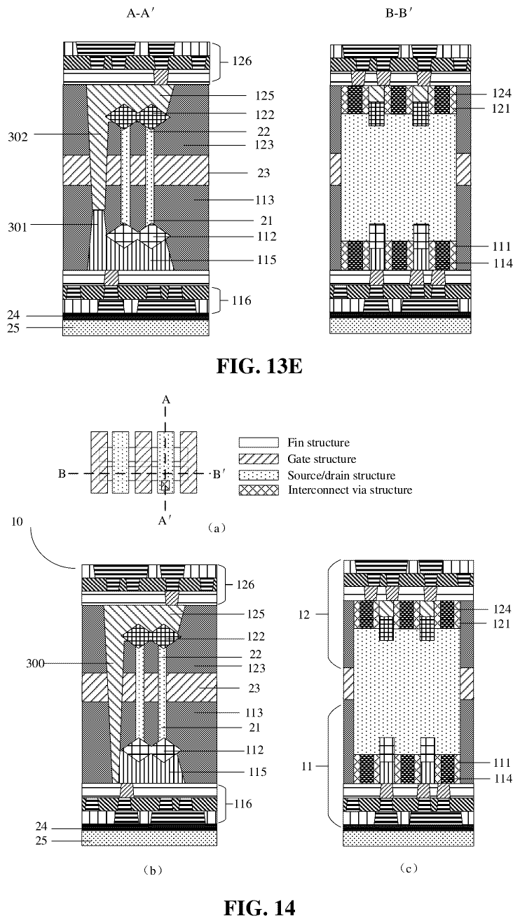

Hereafter, the preparation process of the semiconductor structure shown in FIG. 11 will be described in conjunction with the above-described preparation method. The semiconductor structure shown in FIG. 11 may be prepared with the flow shown in FIG. 13A to FIG. 13E. FIG. 13A to FIG. 13E are schematic diagrams of a preparation process of the semiconductor structure in FIG. 11 according to an embodiment of the present disclosure.

In an example, taking the first transistor 11 and the second transistor 12 as fin field effect transistors as an example, the preparation process of the source-drain interconnected semiconductor structure 10 may include the steps as described below.

First step: a semiconductor substrate 20 (e.g., a Si substrate) is provided (see (a) in FIG. 13A).

Second step: the semiconductor substrate 20 is etched to form a plurality of active structures, the active structure including a first active structure 21 and a second active structure 22 (see fin structures in (b) in FIG. 13A).

Third step: oxide is filed on the semiconductor substrate 20 to form a shallow trench isolation structure 23 (see (c) in FIG. 13A). Here, the shallow trench isolation structure 23, the height of which is greater than the height of the active structures, may cover the active structures. Then, the shallow trench isolation structure 23 is subjected to chemical-mechanical planarization processing.

Fourth step: a portion of the shallow trench isolation structure 23 is etched using standard steps, so that the second portion (i.e., the first active structure 21) of the active structure is exposed (see (a) in FIG. 13B).

Fifth step: polycrystalline silicon is deposited in the gate area of the first transistor 11 to form a first dummy gate structure 28. First dummy gate sidewalls 111 are formed on both sides of the first dummy gate structure 28. The first active structure 21 is then etched to form a source/drain groove of the first transistor 11 (see (b) in FIG. 13B).

Sixth step: epitaxial growth of source/drain is performed within the source/drain groove of the first transistor 11, to form the first source/drain structure 112. Then, a semiconductor material is deposited on the first active structure 21 to form a first interlayer dielectric layer 113 (see (c) in FIG. 13B).

Seventh step: a portion of the first interlayer dielectric layer 113 is removed by etching to form a first groove (not shown), and a metallic material is deposited in the first groove to form a first source/drain metal 115. Next, a third groove (not shown) is formed on the side surface of the first source/drain metal 115 (i.e., the side surface of the source/drain epitaxy) by etching, and a metallic material is deposited in the third groove to form a first interconnect via structure 301, the first interconnect via structure 301 is connected to the first source/drain metal 115 (see (a) in FIG. 13C).

Eighth step: the first dummy gate structure 28 is removed, and metal is deposited in the gate area to form the first gate structure 114. Then, subsequent processes are performed on the first interlayer dielectric layer 113 to form the first metal interconnect layer 116 (see (b) in FIG. 13C).

Ninth step: oxide is deposited on the first metal interconnect layer 116 to form an insulating layer 24, which is bonded to the carrier wafer 25. Next, the first transistor 11 after bond to the carrier wafer 25 is flipped, so that the semiconductor substrate 20 is placed upward (see (c) in FIG. 13C).

Tenth step: the semiconductor substrate 20 is removed by etching and the shallow trench isolation structure 23 is etched, so that the second portion (i.e., the second active structure 22) of the active structure is exposed (see (a) in FIG. 13D).

In some embodiments, when the shallow trench isolation structure 23 is etched, the etching depth is controlled to retain a certain thickness of the shallow trench isolation structure 23. The shallow trench isolation structure 23 is used to isolate the first transistor 11 from the second transistor 12.

Eleventh step: a second source/drain structure 122, a second dummy gate structure 29, a second dummy gate sidewall 121, and a second interlayer dielectric layer 123 are formed on the second active structure 22 (see (b) in FIG. 13D) (see the fifth and sixth steps for the preparation process).

Twelfth step: a portion of the second interlayer dielectric layer 123 is removed by etching to form a second groove (not shown), and a metallic material is deposited in the second groove to form a second source/drain metal 125. Here, the first source/drain metal 115 and the second source/drain metal 125 have the same shape and are disposed opposite to each other. Next, a fourth groove (not shown) is formed on the side surface (the location aligned with the first interconnect via structure 301) of the second source/drain metal 125 by etching. Here, when the fourth groove is etched, etching is not stopped until the fourth groove is communicated with the third groove. A metallic material is deposited in the fourth groove to form a second interconnect via structure 302, the second interconnect via structure 302 being connected to the second source/drain metal 125 (see (c) in FIG. 13D).

Thirteenth step: the second gate structure 124 and the second metal interconnect layer 126 are formed (see the eighth step for the preparation process) (see FIG. 13E).

Now, the first transistor 11 and the second transistor 12 have been prepared. The first transistor 11 and the second transistor 12 are fin field effect transistors, and the first source/drain metal 115 and the second source/drain metal 125 are interconnected by the first interconnect via structure 301 and the second interconnect via structure 302 for the semiconductor structure 10.

The interconnect via structure 300 in the semiconductor structure 10 shown in FIG. 11 is composed of two parts (i.e., the first interconnect via structure 301 and the second interconnect via structure 302), and it can be understood that the interconnect via structure 300 in the semiconductor structure 10 shown in FIG. 11 is formed by two processes. In another embodiment, the interconnect via structure 300 in the semiconductor structure 10 may be formed by one process. FIG. 14 is a schematic structural diagram of a semiconductor structure according to an embodiment of the present disclosure. In FIG. 14, (a) is a top view of the semiconductor structure, for ease of understanding, only the fin structure, the gate structure, and the source/drain structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

Referring to FIG. 14, the semiconductor structure 10 includes a first transistor 11 and a second transistor 12, and the active structure in the semiconductor structure 10 is a plurality of fin structures. The fin structure is divided into upper and lower parts, denoted as a first part and a second portion, respectively, the first part serving as the first active structure 21 in the first transistor 11, and the second portion serving as the second active structure 22 in the second transistor 12. The first source/drain metal 115 in the first transistor 11 and the second source/drain metal 125 in the second transistor 12 are communicate with each other through the interconnect via structure 300. The interconnect via structure 300 is located on one side of the active structure. Both ends of the interconnect via structure 300 are connected to the first source/drain metal 115 and the second source/drain metal 125, respectively. A shallow trench isolation structure 23 is provided between the first transistor 11 and the second transistor 12, and the shallow trench isolation structure 23 is used to isolate the first transistor 11 and the second transistor 12.

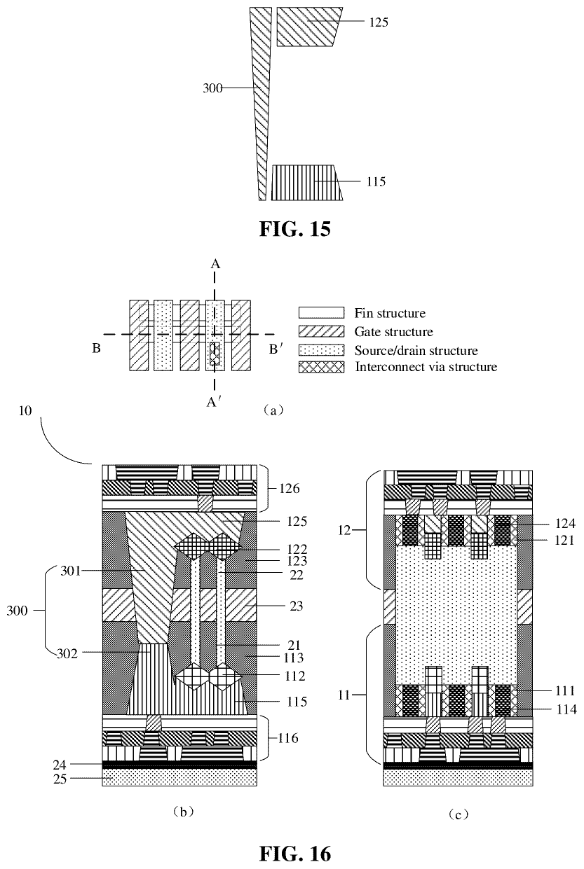

FIG. 15 is a schematic structural diagram of an interconnect via structure according to an embodiment of the present disclosure. FIG. 15 shows a disassembly diagram of the interconnect via structure 300, the first source/drain metal 115, and the second source/drain metal 125. Referring to FIG. 15, the interconnect via structure 300 is drawn out from the second source/drain metal 125 and extends to the first source/drain metal 115. Both ends of the interconnect via structure 300 are connected to the first source/drain metal 115 and the second source/drain metal 125, respectively.

Hereafter, the preparation process of the semiconductor structure shown in FIG. 14 will be described in conjunction with the above-described preparation method.

First step: a silicon substrate is provided.

Second step: the silicon substrate is etched to form a plurality of fin structures.

Third step: a shallow groove isolation structure is formed (see the third step in the preparation process of the semiconductor structure shown in FIG. 11).

Fourth step: the first portion (i.e., the first active structure) of the fin structures are exposed (see the fourth step in the preparation process of the semiconductor structure shown in FIG. 11).

Fifth step: a first dummy gate structure and a spacer are formed (see the fifth step in the preparation process of the semiconductor structure shown in FIG. 11).

Sixth step: a first source/drain structure and a first interlayer dielectric layer are formed (see the sixth step in the preparation process of the semiconductor structure shown in FIG. 11).

Seventh step: a portion of the first interlayer dielectric layer is removed by etching to form a first groove, and a metallic material is deposited in the first groove to form a first source/drain metal.

Eighth step: a first gate structure and a first metal interconnect layer are formed (see the eighth step in the preparation process of the semiconductor structure shown in FIG. 11).

Ninth step: flipping is performed, the semiconductor substrate is removed, and the second portion of the fin structures are exposed (see the ninth step and the tenth step in the preparation process of the semiconductor structure shown in FIG. 11).

Tenth step: a second source/drain structure, a second dummy gate structure and a second interlayer dielectric layer are formed on the second portion of the fin structures (see the fifth step and the sixth step in the preparation process of the semiconductor structure shown in FIG. 11).

Eleventh step: a portion of the second interlayer dielectric layer is removed by etching to form a second groove, and a metallic material is deposited in the second groove to form a second source/drain metal. Here, the first source/drain metal and the second source/drain metal have the same shape and are disposed opposite to each other. Next, a third groove-shaped hole is formed on the side surface of the second source/drain metal by etching. Here, when the third groove-shaped hole is etched, etching is not stopped until the third groove-shaped hole is in contact with the first source/drain metal and the third groove-shaped hole passes through the first interlayer dielectric layer. A metallic material is deposited in the third groove-shaped hole to form the interconnect via structure, and both ends of the interconnect via structure are connected to the first source/drain metal and the second source/drain metal respectively.

Twelfth step: a second gate structure and a second metal interconnect layer are formed (see the eighth step in the preparation process of the semiconductor structure shown in FIG. 11).

At this point, the preparation of the semiconductor structure completes, in which the first transistor and the second transistor are fin field effect transistors, and in which the first source/drain metal and the second source/drain metal are interconnected by the first interconnect via structure and the second interconnect via structure.

In some embodiments, FIG. 16 is a schematic structural diagram of a semiconductor structure according to an embodiment of the present disclosure. In FIG. 16, (a) is a top view of the semiconductor structure, for ease of understanding, only the fin structure, the gate structure, and the source/drain structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

Referring to FIG. 16, the semiconductor structure 10 includes a first transistor 11 and a second transistor 12, and the active structure in the semiconductor structure 10 is a plurality of fin structures. In the A-A′ direction, the location of the plurality of fin structures is biased toward one side (e.g., the A side) of the semiconductor substrate. The fin structure is divided into upper and lower parts, denoted as a first part and a second part, respectively, the first part serving as the first active structure 21 in the first transistor 11, and the second part serving as the second active structure 22 in the second transistor 12. The first source/drain metal 115 in the first transistor 11 and the second source/drain metal 125 in the second transistor 12 are communicate with each other through the interconnect via structure 300. Both ends of the interconnect via structure 300 are connected to the first source/drain metal 115 and the second source/drain metal 125, respectively. A shallow trench isolation structure 23 is provided between the first transistor 11 and the second transistor 12, and the shallow trench isolation structure 23 is used to isolate the first transistor 11 and the second transistor 12.

Referring to FIG. 16 and FIG. 11, the width of the interconnect via structure 300 in FIG. 16 is greater than the width of the interconnect via structure 300 in FIG. 11. This is because the active structure of the semiconductor structure 10 shown in FIG. 16 is biased to one side of the semiconductor other than disposed at the middle position of the semiconductor substrate, and a larger space is reserved for the interconnect via structure 300. The increase in the width of the interconnect via structure 300 may reduce the resistance of the interconnection between the first source/drain structure 112 and the second source/drain structure 122.

In some embodiments, in the process of preparing the semiconductor structure shown in FIG. 16, when the semiconductor substrate is etched to form a fin structure, the etching location is controlled so that the location of the formed fin structure is biased to one side of the semiconductor substrate, and a larger space is reserved on the other side of the semiconductor substrate for subsequent preparation of the interconnect via structure 300. In the formation of the interconnect via structure, a first deep groove having a larger diameter is formed by etching, and then a metallic material is deposited in the first deep groove having the larger diameter to form the interconnect via structure. The preparation method of other structures in the semiconductor structure 10 shown in FIG. 16 is the same as the preparation method of the semiconductor structure 10 shown in FIG. 11, and the preparation process of the semiconductor structure 10 shown in FIG. 11 can be referred to.

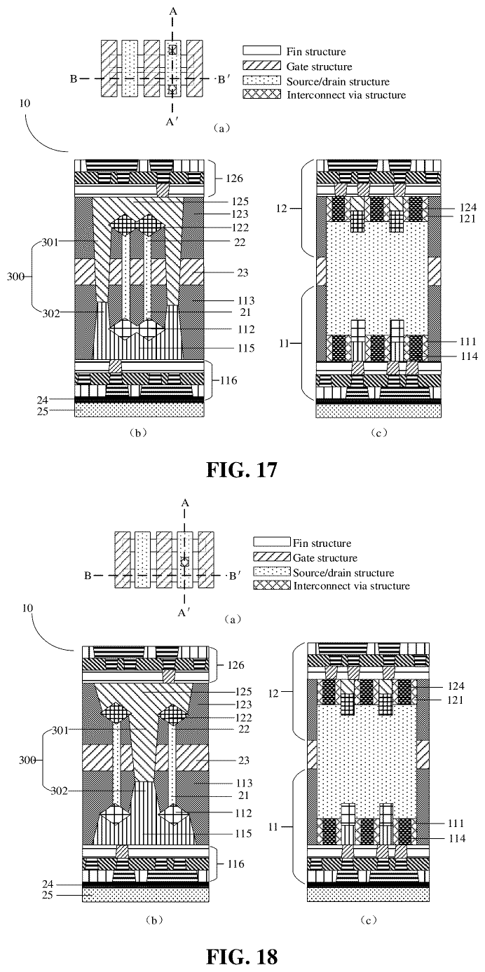

In some embodiments, FIG. 17 is a schematic structural diagram of a semiconductor structure according to an embodiment of the present disclosure. In FIG. 17, (a) is a top view of the semiconductor structure, for ease of understanding, only the fin structure, the gate structure, and the source/drain structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

Referring to FIG. 17, the semiconductor structure 10 includes a first transistor 11 and a second transistor 12, and the active structure in the semiconductor structure 10 is a plurality of fin structures. The fin structure is divided into upper and lower parts, denoted as a first part and a second part, respectively, the first part serving as the first active structure 21 in the first transistor 11, and the second part serving as the second active structure 22 in the second transistor 12. The first source/drain metal 115 in the first transistor 11 and the second source/drain metal 125 in the second transistor 12 are communicate with each other through interconnect via structures 300. The interconnect via structures 300 are located on both sides of the active structure, and both ends of the interconnect via structures 300 are connected to the first source/drain metal 115 and the second source/drain metal 125, respectively. A shallow trench isolation structure 23 is provided between the first transistor 11 and the second transistor 12, and the shallow trench isolation structure 23 is used to isolate the first transistor 11 and the second transistor 12.

In some embodiments, in the process of preparing the semiconductor structure shown in FIG. 17, when the interconnect via structures 300 are formed, etching is performed on both sides of the active structure to form first deep grooves, and the interconnect via structures 300 located on both sides of the active structure are formed in the first deep grooves. The preparation method of other structures in the semiconductor structure 10 shown in FIG. 17 is the same as the preparation method of the semiconductor structure 10 shown in FIG. 11, and the preparation process of the semiconductor structure 10 shown in FIG. 11 can be referred to.

In some embodiments, FIG. 18 is a schematic structural diagram of a semiconductor structure according to an embodiment of the present disclosure. In FIG. 18, (a) is a top view of the semiconductor structure, for ease of understanding, only the fin structure, the gate structure, and the source/drain structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

Referring to FIG. 18, the semiconductor structure 10 includes a first transistor 11 and a second transistor 12, and the active structure in the semiconductor structure 10 is a plurality of fin structures. The fin structure is divided into upper and lower parts, denoted as a first part and a second portion, respectively, the first part serving as the first active structure 21 in the first transistor 11, and the second portion serving as the second active structure 22 in the second transistor 12. The first source/drain metal 115 in the first transistor 11 and the second source/drain metal 125 in the second transistor 12 are communicate with each other through an interconnect via structure 300. The interconnect via structure 300 is located in the middle of adjacent source/drain epitaxy (which can be understood as being located in the middle location of the fin structures), and both ends of the interconnect via structure 300 are connected to the first source/drain metal 115 and the second source/drain metal 125, respectively. A shallow trench isolation structure 23 is provided between the first transistor 11 and the second transistor 12, and the shallow trench isolation structure 23 is used to isolate the first transistor 11 and the second transistor 12.

In some embodiments, in the process of preparing the semiconductor structure 10 shown in FIG. 18, the spacing between fin structures is increased in the formation of the fin structures on the semiconductor substrate by etching, and when the source-drain epitaxy is grown, the source epitaxy and the drain epitaxy are not merged when the source/drain epitaxy are grown, the location for the interconnect via structure is reserved between the fin structures and between the source epitaxy and the drain epitaxy. When the interconnect via structure is formed, a first deep groove is formed by etching in the middle of the active structure, and the interconnect via structure located in the middle of the active structure is formed in the first deep groove. The preparation method of other structures in the semiconductor structure 10 shown in FIG. 18 is the same as the preparation method of the semiconductor structure shown in FIG. 11, and the preparation process of the semiconductor structure shown in FIG. 11 can be referred to.

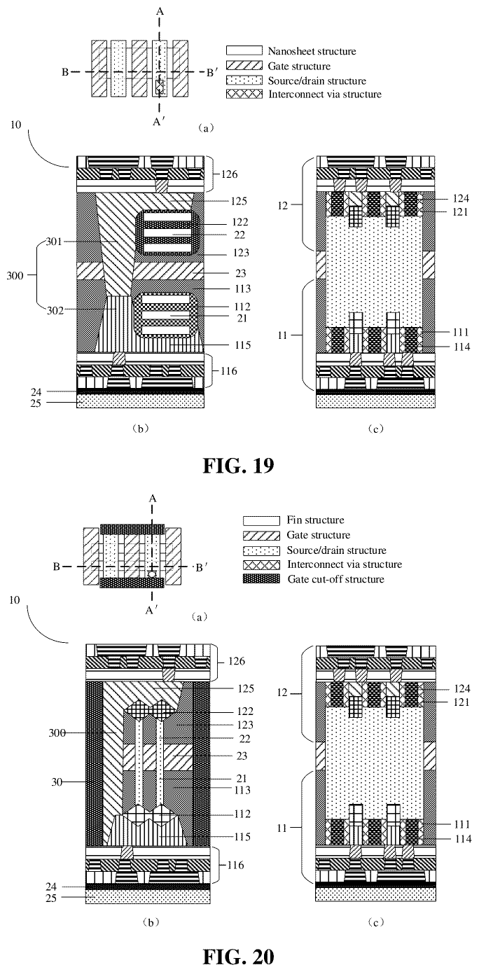

In some embodiments, FIG. 19 is a schematic structural diagram of a semiconductor structure according to an embodiment of the present disclosure. In FIG. 19, (a) is a top view of the semiconductor structure, for ease of understanding, only the nanosheet structure, the gate structure, and the source/drain structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

Referring to FIG. 19, the semiconductor structure 10 includes a first transistor 11 and a second transistor 12, and the active structure in the semiconductor structure 10 is a plurality of nanosheet structures. The nanosheet structures are divided into upper and lower parts, denoted as a first part and a second part, respectively, the first part serving as the first active structure 21 in the first transistor 11, and the second part serving as the second active structure 22 in the second transistor 12. The first source/drain metal 115 in the first transistor 11 and the second source/drain metal 125 in the second transistor 12 are communicate with each other through an interconnect via structure 300. The interconnect via structure 300 is located on one side of the active structure, and both ends of the interconnect via structure 300 are connected to the first source/drain metal 115 and the second source/drain metal 125, respectively. A shallow trench isolation structure 23 is provided between the first transistor 11 and the second transistor 12, and the shallow trench isolation structure 23 is used to isolate the first transistor 11 and the second transistor 12.

In some embodiments, in the process of preparing the semiconductor structure shown in FIG. 19, when the semiconductor substrate is etched to form the nanosheet structure, the etching location is controlled so that the location of the formed nanosheet structure is biased to one side of the semiconductor substrate, and a larger space is reserved on the other side of the semiconductor substrate for subsequent preparation of the interconnect via structure. In the formation of the interconnect via structure, a first deep groove having a larger diameter is formed by etching, and then a metallic material is deposited in the first deep groove to form the interconnect via structure. The preparation method of other structures in the semiconductor structure 10 shown in FIG. 19 is the same as the preparation method of the semiconductor structure 10 shown in FIG. 11, and the preparation process of the semiconductor structure 10 shown in FIG. 11 can be referred to.

In the embodiments of the present disclosure, the interconnect via structure in the semiconductor structure passes through the first interlayer dielectric layer and the second interlayer dielectric layer to implement interconnection between the first source/drain structure and the second source/drain structure. Since the interconnect via structure passes through the first interlayer dielectric layer and the second interlayer dielectric layer, the etching may be stopped at the source/drain metal by means of selective etching, thereby reducing the difficulty of controlling the etching time in the source-drain interconnection scheme. Further, the interconnect via structure may be disposed at any one of the following locations: one side of the active structure, both sides of the active structure, and the middle of the active structure, which makes the interconnection of the first source/drain structure and the second source/drain structure in the semiconductor structure more flexible.

FIG. 20 is a schematic structural diagram of a semiconductor structure according to an embodiment of the present disclosure. In FIG. 20, (a) is a top view of the semiconductor structure, for ease of understanding, only the fin structure, the gate structure, the source/drain structure, the gate cut-off structure, the source/drain metal, and the interconnect via structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

Referring to FIG. 20, the semiconductor structure 10 includes a first semiconductor structure 11 and a second semiconductor structure 12, and the active structure in the semiconductor structure 10 is a plurality of fin structures. The fin structure is divided into upper and lower parts, denoted as a first part and a second part, respectively, the first part serving as the first active structure 21 in the first transistor 11, and the second part serving as the second active structure 22 in the second transistor 12. The first source/drain metal 115 in the first transistor 11 and the second source/drain metal 125 in the second transistor 12 are communicate with each other through an interconnect via structure 300. A shallow trench isolation structure 23 is provided between the first transistor 11 and the second transistor 12, and the shallow trench isolation structure 23 is used to isolate the first transistor 11 and the second transistor 12. In the A-A′ direction, both sides of the fin structure have gate cut-off structures 30. The interconnect via structure 300 is located between the edge of the gate cut-off structure 30 and the edge of the second source/drain metal 125.

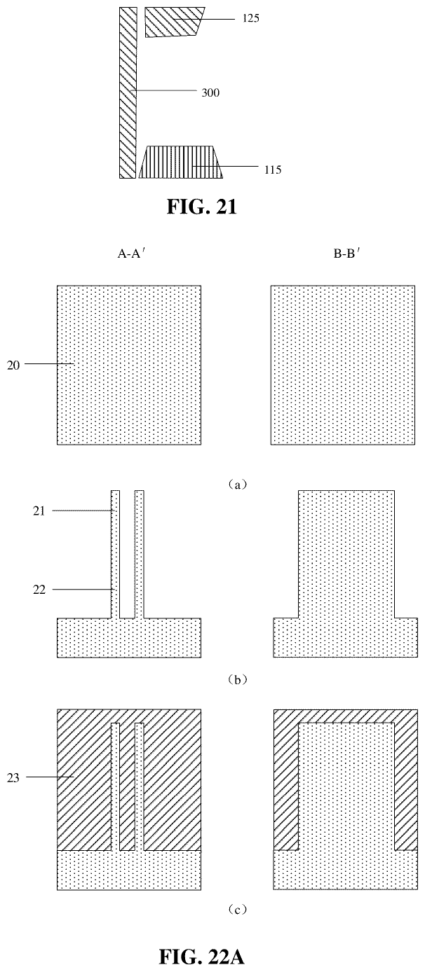

FIG. 21 is a schematic structural diagram of an interconnect via structure according to an embodiment of the present disclosure. FIG. 21 shows a disassembly diagram of the interconnect via structure 300, the first source/drain metal 115, and the second source/drain metal 125. Referring to FIG. 21, the interconnect via structure 300 is drawn out from the second source/drain metal 125 and extends to the first source/drain metal 115. Both ends of the interconnect via structure 300 are connected to the first source/drain metal 115 and the second source/drain metal 125, respectively.

In the embodiments of the present disclosure, the first active structure 21 of the first transistor 11 and the second active structure 22 of the second transistor 12 are formed by the same etching process, so that self-alignment of the first transistor 11 and the second transistor 12 can be realized.

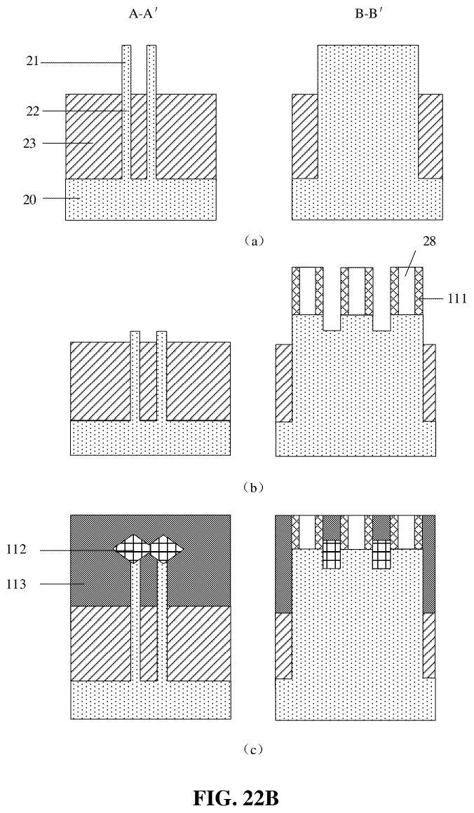

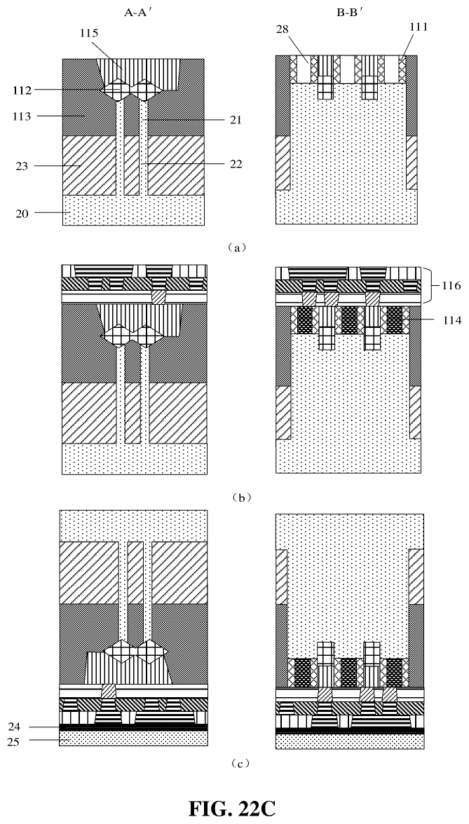

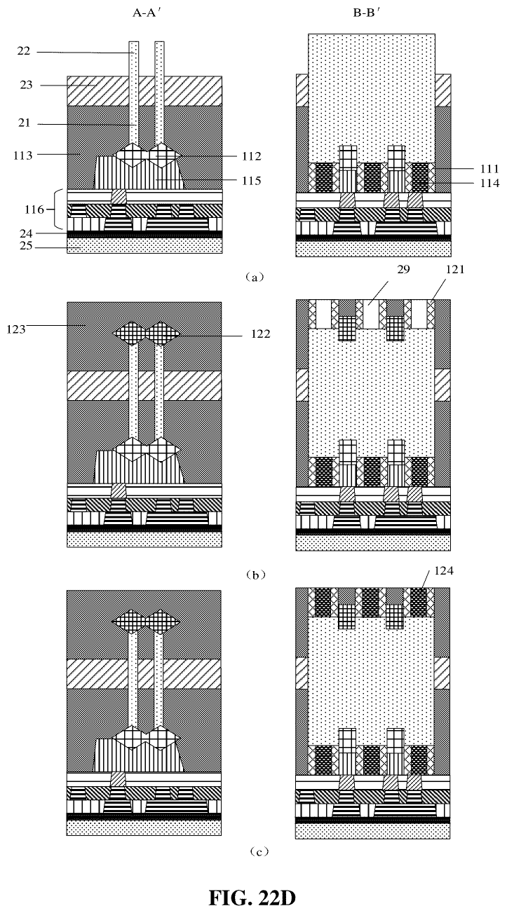

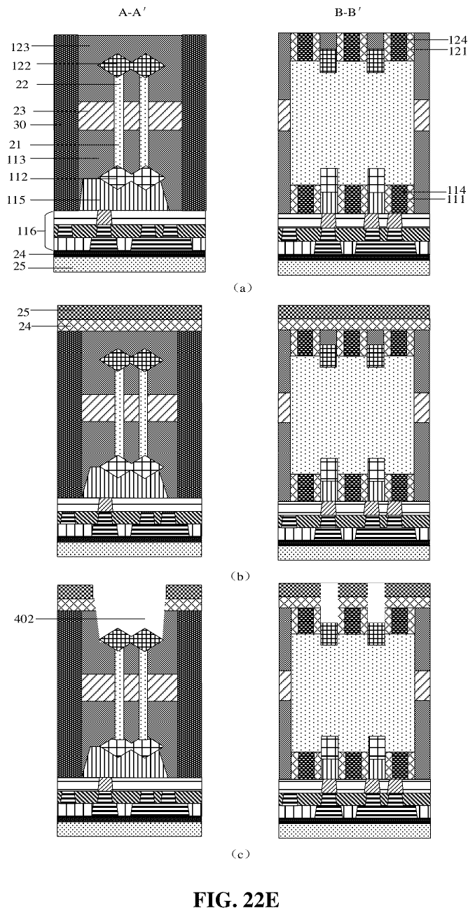

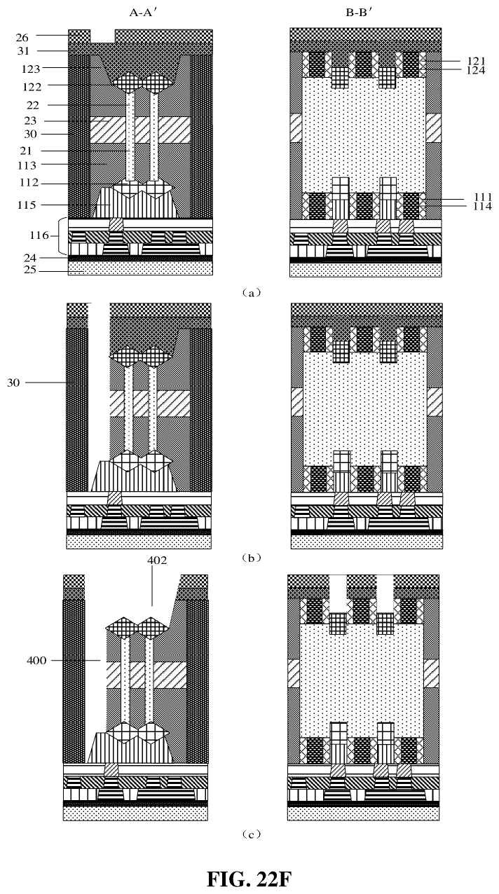

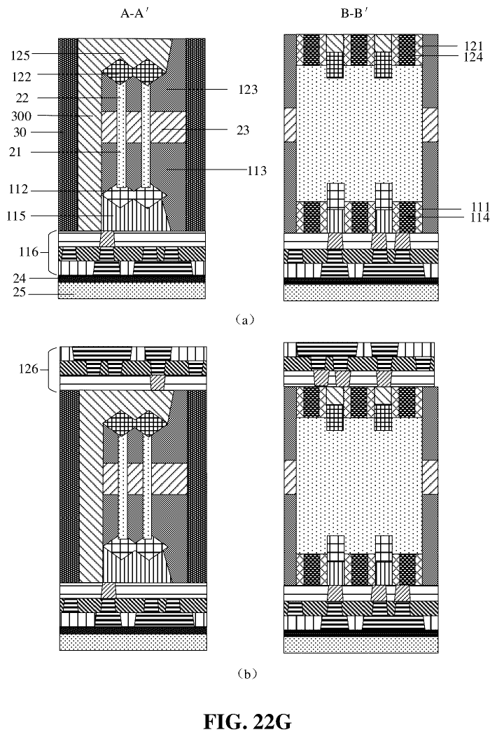

Hereafter, the preparation process of the semiconductor structure shown in FIG. 20 will be described in conjunction with the above-described preparation method. The semiconductor structure shown in FIG. 20 may be prepared with the flow shown in FIG. 22A to FIG. 22G. FIG. 22A to FIG. 22G are schematic diagrams of a preparation process of the semiconductor structure in FIG. 20 according to an embodiment of the present disclosure.

In an example, taking the first transistor 11 and the second transistor 12 as fin field effect transistors as an example, a first preparation process of the source-drain interconnected semiconductor structure 10 may include the steps as described below.

First step: a semiconductor substrate 20 (e.g., a Si substrate) is provided (see (a) in FIG. 22A).

Second step: the semiconductor substrate 20 is etched to form a plurality of active structures (fin structures), the active structure including a first active structure 21 and a second active structure 22 (see (b) in FIG. 22A).

Third step: oxide is filed on the semiconductor substrate 20 to form a shallow trench isolation structure 23 (see (c) in FIG. 22A). Here, the shallow trench isolation structure 23, the height of which is greater than the height of the active structures, may cover the active structures. Then, the shallow trench isolation structure 23 is subjected to chemical-mechanical planarization processing.

Fourth step: a portion of the shallow trench isolation structure 23 is etched using standard steps, so that the second portion (i.e., the first active structure 21) of the fin structure is exposed (see (a) in FIG. 22B).

Fifth step: polycrystalline silicon is deposited in the gate area of the first transistor 11 to form a first dummy gate structure 28, first dummy gate sidewalls 111 are formed on both sides of the first dummy gate structure 28. The first active structure 21 is then etched to form a source/drain groove of the first transistor 11 (see (b) in FIG. 22B).

Sixth step: epitaxial growth of source/drain is performed within the source/drain groove of the first transistor 11, to form the first source/drain structure 112. Then, a semiconductor material is deposited on the first active structure 21 to form a first interlayer dielectric layer 113 (see (c) in FIG. 22B).

Seventh step: a portion of the first interlayer dielectric layer 113 is removed by etching to form a first groove (not shown), and a metallic material is deposited in the first groove to form a first source/drain metal 115. (see (a) in FIG. 22C).

Eighth step: the first dummy gate structure 28 is removed, and metal is deposited in the gate area of the first semiconductor structure to form the first gate structure 114. Then, subsequent processes are performed on the first interlayer dielectric layer 113 to form the first metal interconnect layer 116 (see (b) in FIG. 22C).

Ninth step: oxide is deposited on the first metal interconnect layer 116 to form an insulating layer 24, which is bonded to the carrier wafer 25. Next, the first transistor 11 after bond to the carrier wafer 25 is flipped, so that the semiconductor substrate 20 is placed upward (see (c) in FIG. 22C).

Tenth step: the semiconductor substrate 20 is removed by etching and the shallow trench isolation structure 23 is etched, so that the second portion (i.e., the second active structure 22) of the active structure is exposed (see (a) in FIG. 22D).

In some embodiments, when the shallow trench isolation structure 23 is etched, the etching depth is controlled to retain a certain thickness of the shallow trench isolation structure 23. The shallow trench isolation structure 23 is used to isolate the first transistor 11 from the second transistor 12.

Eleventh step: a second source/drain structure 122, a second dummy gate structure 29, a second dummy gate sidewall 121, and a second interlayer dielectric layer 123 are formed on the second active structure 22 (see (b) in FIG. 22D) (see the fifth and sixth steps for the preparation process).

Twelfth step: the second dummy gate structure 29 is removed, and metal is deposited in the gate area of the second semiconductor structure to form the second gate structure 124 (see (c) in FIG. 22D) (see the eighth step for the preparation process).

Thirteenth step: the first gate structure 114 and the second gate structure 124 are subjected to a gate cutting process to form the gate cut-off structure 30 (see (a) in FIG. 22E).

Fourteenth step: an anti-reflective material is deposited on the second interlayer dielectric layer 123 to form the anti-reflective layer 31; the photoresist 26 is then deposited on the anti-reflective layer 31 (see (b) in FIG. 22E).

Fifteenth step: the photoresist 26, the anti-reflective layer 31, and a portion of the second interlayer dielectric layer 123 are etched to form the second groove 402 (see (c) in FIG. 22E).

Sixteenth step: the anti-reflective material is deposited in the second groove 402, and the anti-reflective material is deposited again at the location of the anti-reflective layer 31 that has been etched away to form a new anti-reflective layer 31; the photoresist 26 is deposited again at the location where the photoresist 26 has been removed; the new photoresist 26 has no photoresist deposited in the area between the edge of the gate cut-off structure 30 and the edge of the second source/drain structure 122, forming a notch, the notch corresponds to the lithographic area self-aligned to the gate cut-off structure 30 and is used for subsequent etching of the first deep groove 400 (see (a) in FIG. 22F).

Seventeenth step: etching is performed downwards on the second interlayer dielectric layer 123 and the first interlayer dielectric layer 113 along the notch of the new photoresist 26 to form the first deep groove 400, the first deep groove passes through the second interlayer dielectric layer 123 and the first interlayer dielectric layer 113 and is communicated with the first source/drain metal 115 (see (b) in FIG. 22F).

Eighteenth step: the anti-reflective material located in the second groove 402 is removed by etching until the second source/drain structure 122 is exposed (see (c) in FIG. 22F).

Nineteenth step: after the new photoresist 26 and the new anti-reflective layer 31 are removed, a metallic material is deposited in the second groove 402 and the first deep groove 400 to form the second source/drain metal 125 and the interconnect via structure 300 (see (a) in FIG. 22G).

Twentieth step: a second metal interconnect layer 126 is formed (see (b) in FIG. 22G) (see the eighth step for a specific preparation process).

Now, the first transistor 11 and the second transistor 12 have been prepared. The first transistor 11 and the second transistor 12 are fin field effect transistors, and the first source/drain metal 115 and the second source/drain metal 125 are interconnected by the interconnect via structure 300 for the semiconductor structure 10.

In the embodiments of the present disclosure, in the process of etching the first deep groove, none of the gate cut-off structure, the second source/drain structure, the first source/drain structure, and the first source/drain metal are etched, so while keeping the area of the first deep groove relatively large, a shift to the left or right to a certain extent may be made during etching to form the first deep groove of different shapes.

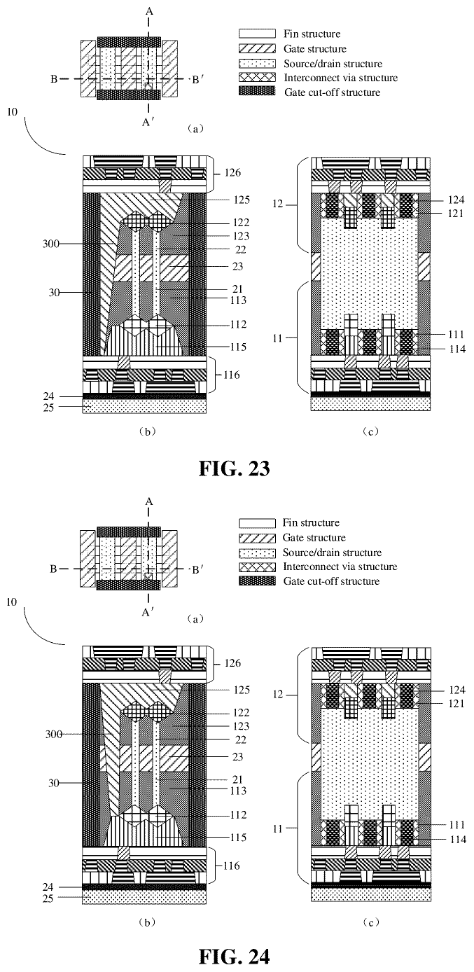

In some embodiments, when the etching is shifted to the left in the process of etching the first deep groove, the formed semiconductor structure is shown in FIG. 23. FIG. 23 is a structural schematic diagram of a semiconductor structure provided according to an embodiment of the present disclosure. In FIG. 23, (a) is a top view of the semiconductor structure, for ease of understanding, only the fin structure, the gate structure, the source/drain structure, the gate cut-off structure, the source/drain metal, and the interconnect via structure are shown in this top view; (b) is a cross-section view of the semiconductor structure taken along the sectioning direction of the source/drain structure (i.e., the A-A′ direction); (c) is a cross-section view of the semiconductor structure taken as the sectioning direction of the gate structure (i.e., the B-B′ direction).

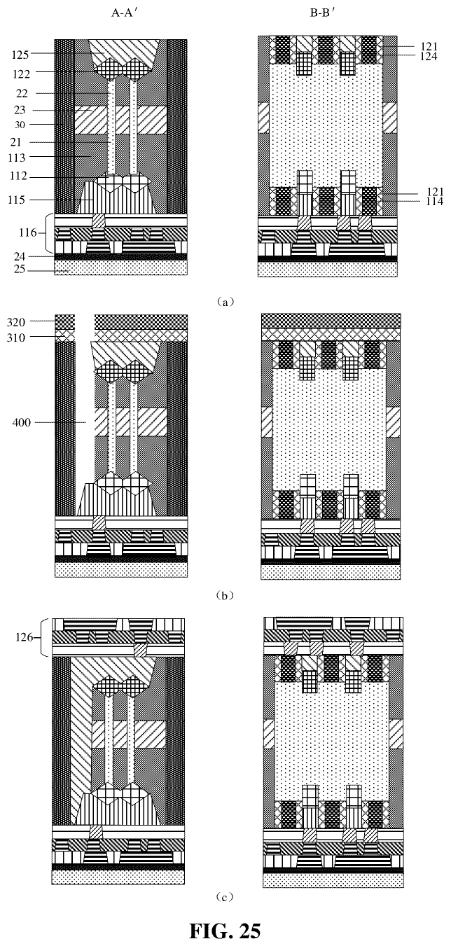

In some other embodiments, when the etching is shifted to the right in the process of etching the first deep groove, the formed semiconductor structure is shown in FIG. 24. FIG. 24 is a structural schematic diagram of a semiconductor structure provided according to an embodiment of the present disclosure. In FIG. 24, (a) is a top view of the semiconductor structure, for ease of understanding, only the fin structure, the gate structure, the source/drain structure, the gate cut-off structure, the source/drain metal, and the interconnect via structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

In some embodiments, the shift of the etching does not affect the self-alignment performance of the interconnect via structure.

In the above preparation flow shown in FIGS. 22A to 22G, the first deep groove is formed by etching, and then the second groove is formed by etching, the second source/drain metal and the interconnect via structure are formed by the same process. The embodiments of the present disclosure do not limit the preparation sequence of the first deep groove and the second groove, nor do they likewise limit the preparation sequence of the second source/drain metal and the interconnect via structure.

FIG. 25 is a schematic diagram of a preparation process of the semiconductor structure in FIG. 20 according to an embodiment of the present disclosure. The semiconductor structure shown in FIG. 20 may be prepared through the flow shown in FIG. 25. FIG. 25 shows a preparation flow different from that of FIGS. 22A to 22G.

In an example, taking the first transistor 11 and the second transistor 12 as fin field effect transistors as an example, the preparation process of the source-drain interconnected semiconductor structure 10 may include the steps as described below.

Here, the first to fifteenth steps of the preparation process of the source-drain interconnected semiconductor structure 10 are the same as the first to fifteenth steps of the above preparation process of the semiconductor structure shown in FIG. 20, and the preparation process may be seen in the above embodiments.

Sixteenth step: the photoresist 32 and the anti-reflective layer 31 are removed, and a metallic material is deposited in the second groove (not shown) to form the second source/drain metal 125 (see (a) in FIG. 25).

Seventeenth step: an anti-reflective material is deposited to form a new anti-reflective layer 31; a photoresist is deposited to form a new photoresist 26; etching is performed downwards on the new photoresist 26, the new anti-reflective layer 31, the second interlayer dielectric layer 123, and a portion of the first interlayer dielectric layer 113 in the area located between the edge of the gate cut-off structure 30 and the edge of the second source/drain structure 122 to form a first deep groove 400, and the etching is stopped when the first deep groove 400 is in communication with the first source/drain metal 115 (see (b) in FIG. 25).

Eighteenth step: after the new photoresist 26 and the new anti-reflective layer 31 are removed, a metallic material is deposited in the first deep groove 400 to form the interconnect via structure 300. And the BEOL process is performed on the second interlayer dielectric layer 123 to form the second metal interconnect layer 126 (see (c) in FIG. 25) (see the twentieth step in the preparation process of the semiconductor structure shown in FIG. 20).

At this point, the preparation of the semiconductor structure 10 completes, in which the first transistor 11 and the second transistor 12 are fin field effect transistors, and the first source/drain metal 115 and the second source/drain metal 125 are interconnected by the interconnect via structure 300.

In the embodiments of the present disclosure, the interconnect via structure in the semiconductor structure connects the first source/drain metal of the first transistor and the second source/drain metal of the second transistor, implementing the interconnection between the first source/drain structure of the first transistor and the second source/drain structure of the second transistor.

Further, the preparation process, which lithographs the first interlayer dielectric layer of the first transistor and the second interlayer dielectric layer of the second transistor based on the lithographic area self-aligned to the gate cut-off structure to form the first deep groove, and deposits metal in the first deep groove to form the interconnect via structure, results in self-alignment of the interconnect via structure.

Further, since the interconnect via structure has self-alignment, the requirement for alignment accuracy can be reduced, and the etching of the the interlayer dielectric layer at the edge of the device when alignment error occurs can be avoided, thereby reducing the occurrence of short-circuit between adjacent devices.

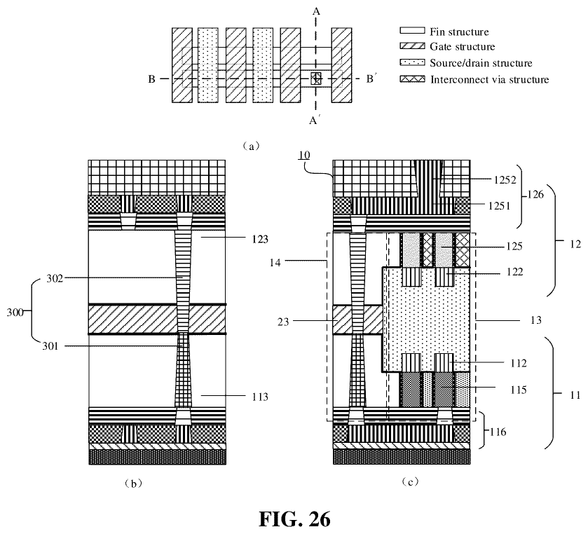

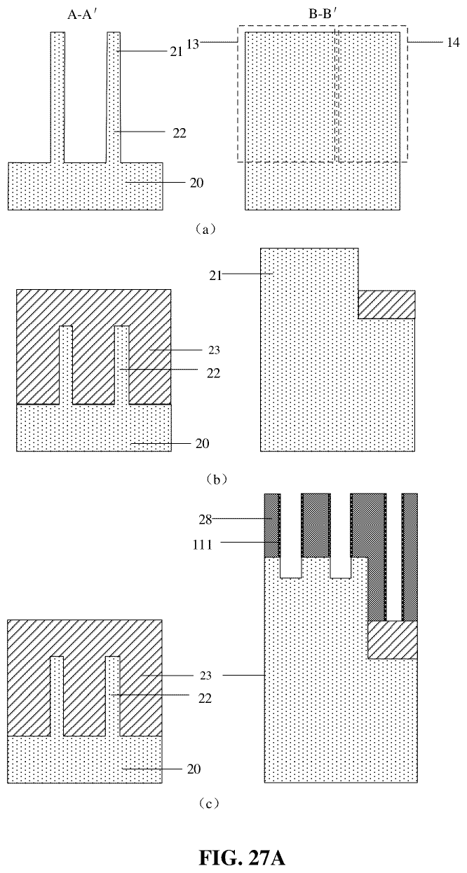

FIG. 26 is a schematic structural diagram of a semiconductor structure according to an embodiment of the present disclosure. In FIG. 26, (a) is a top view of the semiconductor structure, for ease of understanding, only the fin structure, the gate structure, the source/drain structure and the interconnect via structure are shown in this top view; (b) is a cross-section view of the semiconductor structure taken along a cross-section of the source/drain structure (i.e., the A-A′ direction); (c) is a cross-section view of the semiconductor structure taken as a cross-section of the gate structure (i.e., the B-B′ direction).

Referring to FIG. 26, the semiconductor structure 10 includes a first transistor 11 and a second transistor 12, and the active structure in the semiconductor structure 10 is a plurality of fin structures. The fin structure is divided into upper and lower parts, denoted as a first part and a second part, respectively, the first part serving as the first active structure 21 in the first transistor 11, and the second part serving as the second active structure 22 in the second transistor 12.

In an embodiment, along the B-B′ direction, the fin structure includes a device area 13 (shown by a dashed box in the figure) and a field area 14 (shown by a dashed box in the figure), wherein the device area 13 is formed with a first source/drain structure 112 and a second source/drain structure 122 which are disposed opposite to each other, the field area 14 is formed with a first interlayer dielectric layer 113 and a second interlayer dielectric layer 123. The first source/drain structure 112 is connected to a first source/drain metal 115, and the first source/drain metal 115 is connected to a first metal interconnect layer 116. The second source/drain structure 122 is connected to a second source/drain metal 125, and the second source/drain metal 125 is connected to a second metal interconnect layer 126. The first source/drain metal 115 of the first transistor 11 is communicated with the second source/drain metal 125 of the second transistor 12 through an interconnect via structure 300, the interconnect via structure 300 passes through the first interlayer dielectric layer 113 of the first transistor 11 and the second interlayer dielectric layer 123 of the second transistor 12.

In an embodiment, referring to FIG. 26, the interconnect via structure 300 may include two parts, one part is a first interconnect via structure 301, and the first interconnect via structure 301 is connected to the first metal interconnect layer 116; the other part is a second interconnect via structure 302, and the second interconnect via structure 302 is connected to the second metal interconnect layer 126; the first interconnect via structure 301 and the second interconnect via structure 302 are connected.

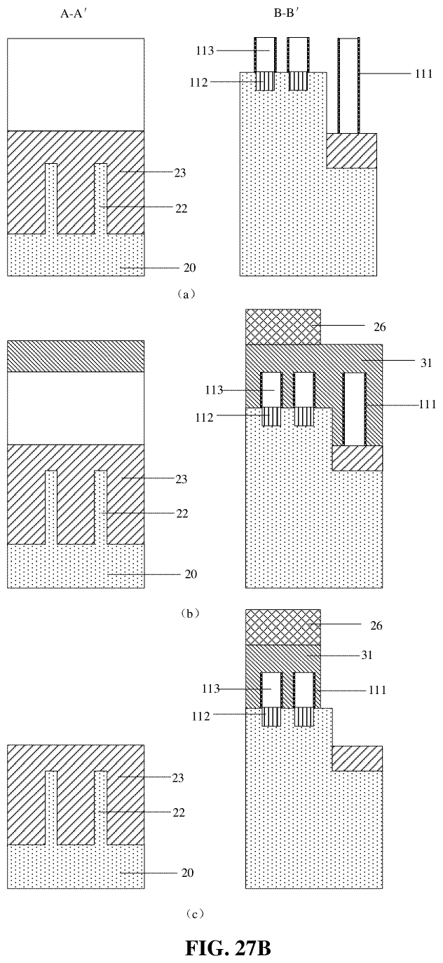

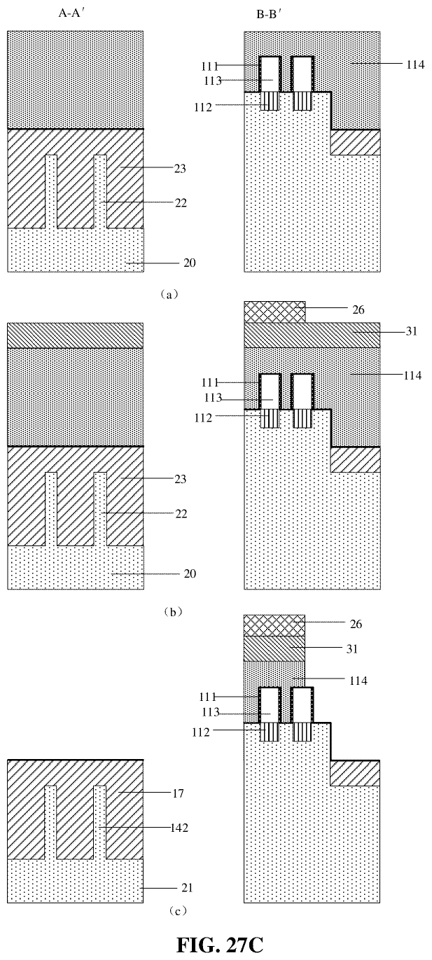

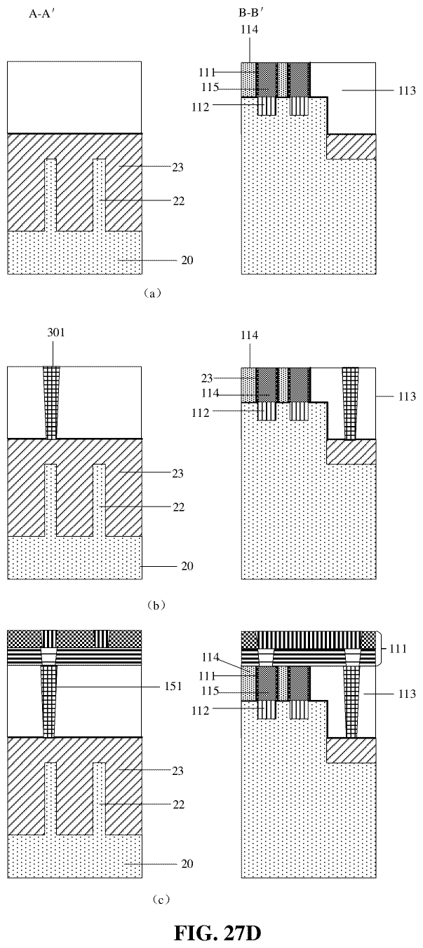

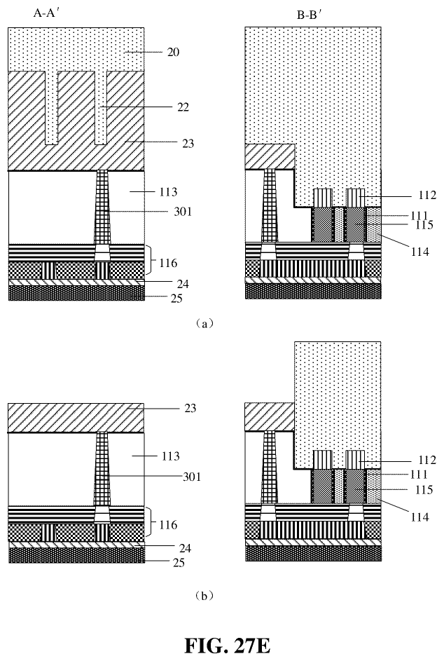

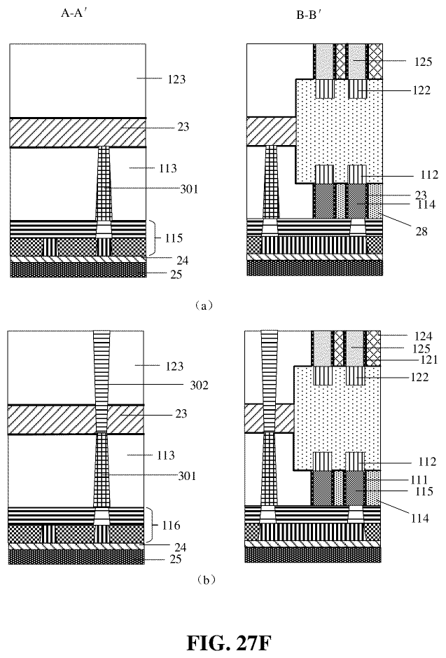

Hereafter, the preparation process of the semiconductor structure shown in FIG. 26 will be described. The semiconductor structure shown in FIG. 26 may be prepared with the flow shown in FIG. 27A to FIG. 27F. FIG. 27A to FIG. 27F are schematic diagrams of a preparation process of the semiconductor structure in FIG. 26 according to an embodiment of the present disclosure.

In an example, the preparation process of the semiconductor structure 10 may include the steps as described below.

First step: a semiconductor substrate 20, on which active structures (including first active structures 21 and second active structures 22) are formed, is provided (see (a) in FIG. 27A).

In an embodiment, active structures (fin structures) may be formed on a silicon substrate using an etching process. The active structures include a device area 13 and a field area 14 arranged in a third direction. The third direction is the same as the extension direction of the active structure, and the third direction is the same as the B-B′ direction.

In an embodiment, the height of the active structures may be greater than 100 nm.

Second step: the first portion (i.e., the first active structures 21) of the active structures close to the right side (field area 14) in the B-B′ direction is removed by lithographing, and the second portion (i.e., the second active structures 22) of the active structures is retained. A semiconductor material is deposited on the second active structures 22 to form a shallow trench isolation structure 23 (see (b) in FIG. 27A).

In an embodiment, the shallow trench isolation structure 23 overlies the top of the second active structures 22 and fills the trench between the active structures.

Third step: the formation of first dummy gate structures 28 and first dummy gate sidewalls 111 is completed on the first active structures 21, and source/drain grooves of the source/drain area are formed by a selective etching process (see (c) in FIG. 27A).

In an embodiment, the first dummy gate structures 28 are arranged at intervals in the B-B′ direction.

Step 4: first source/drain structures 112 are formed at the source/drain grooves, and a semiconductor material is deposited on the first source/drain structures 112 to form a first interlayer dielectric layer 113. Subsequently, after a planarization process is performed, the first dummy gate structures 28 are removed (see (a) in FIG. 27B).

Fifth step: an anti-reflective layer 31 and a photoresist 26 are deposited and formed on the first active structures 21 (see (b) in FIG. 27B).

In an embodiment, the topography of the photoresist is shown as the photoresist 26 in FIG. 27B. The function of this lithography is to remove the first interlayer dielectric layer 113 and the first dummy gate sidewalls 111 in the field area.

In an embodiment, the first interlayer dielectric layer 113 and the first dummy gate sidewalls 111 in the field area may not be removed.

Sixth step: the anti-reflective layer 31, the first interlayer dielectric layer 113 and the first dummy gate sidewalls 111, which are not covered with the photoresist 26, are etched (see (c) in FIG. 27B).

In an embodiment, the removal of the first interlayer dielectric layer 113 in this step is self-aligned, allowing for a certain degree of shift.

Seventh step: the photoresist 26 and the anti-reflective layer 31 are removed, and the formation of the first gate structure 114 is completed by a standard semiconductor manufacturing process (see (a) in FIG. 27C).

In an embodiment, the formed first gate structure 114 may include a deposited gate dielectric layer and a deposited gate electrode layer.

In an embodiment, the first gate structure 114 may be formed within the device area 13, and the first interlayer dielectric layer 113 may be formed within the field area 14.

Eighth step: an anti-reflective layer 31 and a photoresist 26 are deposited and formed on the first gate structure 114 (see (b) in FIG. 27C).

In an embodiment, the topography of the photoresist is shown as the photoresist 26 in (b) FIG. 27B. The function of this lithography is to remove the gate structure in the field area 14.

Ninth step: the anti-reflective layer 31 and the first gate structure 114, which are not covered with the photoresist 26, are etched (see (c) in FIG. 27C). This step is performed with self-alignment, allowing for a slight shift of the etch window within the range corresponding to the device area 13 on the right without affecting subsequent structure formation.

In an embodiment, the extent of the pattern used to etch the gate structure in this step is larger than the extent of the pattern used to etch the first interlayer dielectric layer in the sixth step.

Tenth step: the photoresist 26 and the anti-reflective layer 31 are removed. After the semiconductor material is deposited on this semiconductor structure, a planarization process is performed to obtain the first interlayer dielectric layer 113. Also, the first interlayer dielectric layer 113 on the upper portion of the first source/drain structures 112 is removed, and a metallic material is deposited to form a first source/drain metal 115 (see (a) in FIG. 27D).

Eleventh step: etching is performed in the field area 14 of the semiconductor structure 10 with the shallow trench isolation structure 23 as the etching stop layer, so as to obtain a via by etching which passes through the first interlayer dielectric layer 113, and a metallic material is deposited in the via to form a first interconnect via structure 301 (see (b) in FIG. 27D).

Twelfth step: the BEOL interconnection process of the first transistor is completed to form a first metal interconnect layer 116. The first metal interconnect layer 116 is communicated with the first interconnect via structure 301 and the first source/drain metal 115 (see (c) in FIG. 27D).

Thirteenth step: oxide is deposited on the first metal interconnect layer 116 to form an insulating layer 24; the carrier wafer 25 is bonded to the first transistor 11 above the the insulating layer 24 and then flipping is performed (see (a) in FIG. 27E).

Fourteenth step: the semiconductor substrate 20 is removed after flipping, lithography is performed on the structure after removing the semiconductor substrate 20, and the second active structures 22 close to the left side (field area 14) in the B-B′ direction is removed. Then, the shallow trench isolation structure 23 is thinned to a certain height (see (b) in FIG. 27E). After this step is completed, the active structures in the field area 14 have been completely removed.

Fifteenth step: a second source/drain structure 122, a second interlayer dielectric layer 123, and a second gate structure 124 in the second transistor 12 are completed by the same process as the third to tenth steps (see (a) in FIG. 27F).

Sixteenth step: the second interlayer dielectric layer 123 corresponding to the field area 14 is etched until the first interconnect via structure 301 is exposed, thereby obtaining a via which passes through the second interlayer dielectric layer 123 by etching, and a metallic material is deposited in the via to form the second interconnect via structure 302 (see (b) in FIG. 27F).

Seventeenth step: the BEOL interconnection process of the second transistor is completed to form a second metal interconnect layer 126. The second metal interconnect layer 126 is communicated with the second source/drain metal 125 (see FIG. 26).

At this point, the preparation of the first transistor and the second transistor is completed, and the first source/drain metal 115 and the second source/drain metal 125 are interconnected through the first interconnect via structure 301 and the second interconnect via structure 302.

In the embodiments of the present disclosure, the interconnect via structure connecting the first transistor and the second transistor is formed in the field area, so that this interconnect via structure is disposed independently from the source/drain metal in the device area, which enables the signal transmission between the first transistor and the second transistor can pass through the field area or the device area, and the degree of freedom of signal transmission can be effectively improved. Further, the interconnect via structure may be implemented in various approaches, which greatly enhances the diversity of source-drain connection implemented between the first transistor and the second transistor.

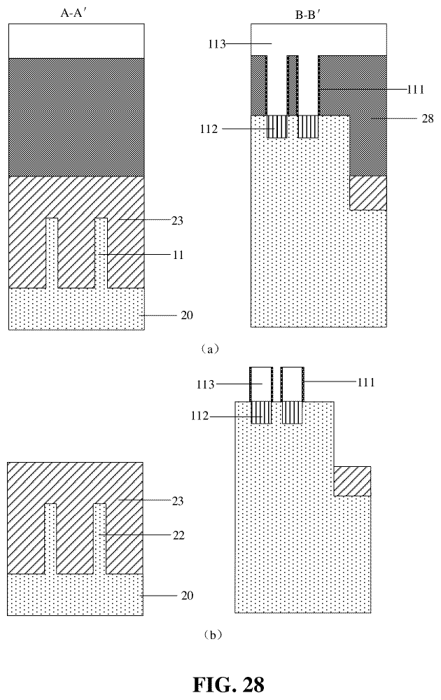

FIG. 28 is a schematic diagram of a preparation process of the semiconductor structure in FIG. 26 according to an embodiment of the present disclosure. The semiconductor structure shown in FIG. 26 may also be prepared by the process in FIGS. 27A to 27F in conjunction with FIG. 28. The preparation process corresponding to FIG. 28 may be described in the above first to seventeenth steps corresponding to FIGS. 27A to 27F. The difference corresponding to FIGS. 27A to 27F above is that in the third step, the field area 14 may be covered by a dummy gate by means of layout design; that is, a wider first dummy gate structure 28 is formed (see (a) in FIG. 28). Then, after the first source/drain structures 112 and the first interlayer dielectric layer 113 are completed in the fourth step, the first dummy gate structures 28 are removed to obtain a target structure in which no first dummy gate structures 28 is contained in the field area (see (b) in FIG. 28). It can be seen that the preparation process corresponding to FIG. 28 does not need to perform lithography in the fifth to seventh steps, thereby reducing one lithography process and reducing the preparation difficulty.

In some embodiments, in the preparation of the second transistor, the same process as the first transistor may be adopted.

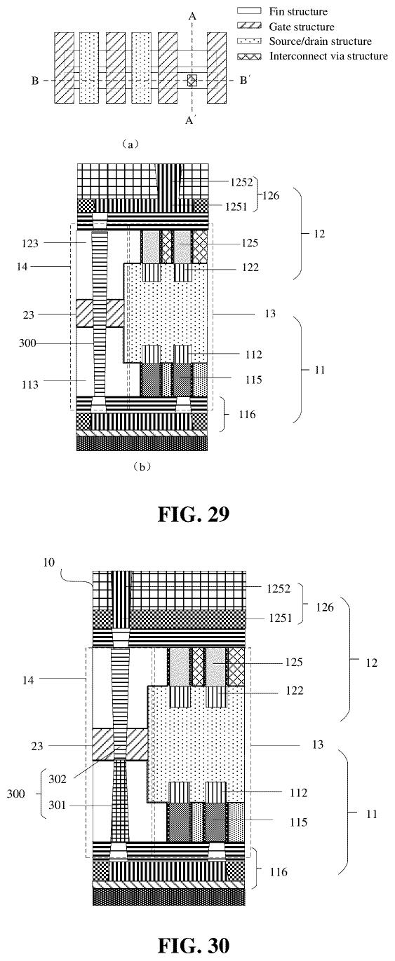

FIG. 29 is a schematic structural diagram of a semiconductor structure according to an embodiment of the present disclosure. In FIG. 29, (a) is a top view of the semiconductor structure, for ease of understanding, only the active structure, the gate structure, the source/drain structure and the interconnect via structure are shown in this top view; (b) is a cross-section view of the semiconductor structure taken as a cross-section of the gate structure (i.e., the B-B′ direction). Unlike the semiconductor structure shown in FIG. 26, the interconnect via structure 300 in the semiconductor structure shown in FIG. 29 has an integral structure. The semiconductor structure shown in FIG. 29 may be formed by changing some steps in the preparation process in the above embodiments. In an embodiment, when the first transistor is prepared, the eleventh step of forming the first interconnect via structure 301 may not be performed; and when the second transistor is prepared, the second interlayer dielectric layer 123 and the first interlayer dielectric layer 113 corresponding to the field area may be etched in the sixteenth step, taking the first metal interconnect layer 116 as the etching stop layer, a first deep groove passing through the second interlayer dielectric layer 123 and the first interlayer dielectric layer 113 may be obtained by etching; and a metal material may be deposited in the first deep groove to form the interconnect via structure 300 to obtain the structure shown in FIG. 29.

FIG. 30 is a schematic structural diagram of a semiconductor structure according to an embodiment of the present disclosure. FIG. 30 is cross-section view of the semiconductor structure taken along the cross-section of the gate structure. As shown in FIG. 26 and FIG. 30, the second metal interconnect layer 126 includes a first interconnect sublayer 1251 (i.e., M0 metal) and a second interconnect sublayer 1252 (i.e., M1 metal). As shown in FIG. 26, the interconnection of the M0 metal and the M1 metal is not implemented as direct interconnection. As shown in FIG. 30, the M0 metal and the M1 metal are directly interconnected, thus making the signal transmission mode between the first transistor and the second transistor more flexible.

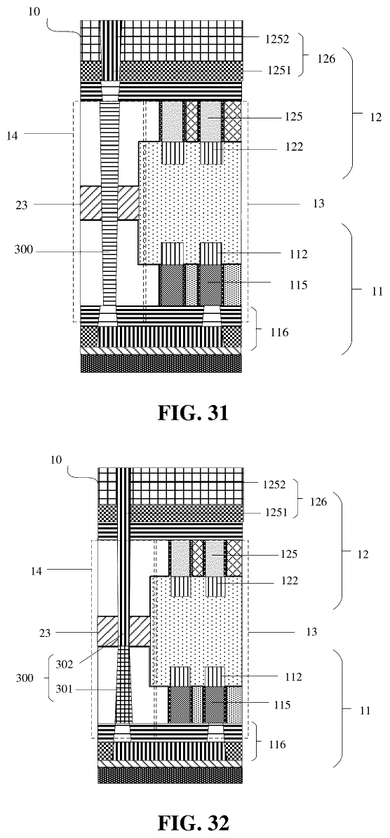

FIG. 31 is a schematic structural diagram of a semiconductor structure according to an embodiment of the present disclosure. FIG. 31 is cross-section view of the semiconductor structure taken along the cross-section of the gate structure. As shown in FIG. 26, the interconnection of the M0 metal and the M1 metal of the second metal interconnect layer 126 is not implemented as direct interconnection. As shown in FIG. 31, the M0 metal and the M1 metal are directly interconnected, thus making the signal transmission mode between the first transistor and the second transistor more flexible.

FIG. 32 is a schematic structural diagram of a semiconductor structure according to an embodiment of the present disclosure. FIG. 32 is cross-section view of the semiconductor structure taken along the cross-section of the gate structure. As shown in FIG. 32, the M0 metal and the M1 metal of the second metal interconnect layer 126, as well as the second interconnect via structure 302, are directly interconnected, thus making the signal transmission mode between the first transistor and the second transistor more flexible.

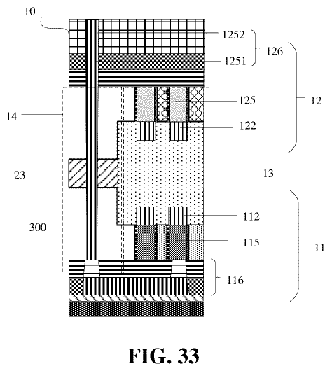

FIG. 33 is a schematic structural diagram of a semiconductor structure according to an embodiment of the present disclosure. FIG. 33 is cross-section view of the semiconductor structure taken along the cross-section of the gate structure. As shown in FIG. 33, the M0 metal and the M1 metal of the second metal interconnection layer 126, as well as the interconnect via structure 300, are directly interconnected, thereby making the signal transmission mode between the first transistor and the second transistor more flexible.

In one or more of the above embodiments, a plurality of metal interconnection schemes can be implemented, and can be implemented in a self-aligned manner, so that the signal transmission mode of the first transistor and the second transistor is more flexible and is not constrained by the source-drain direct connection structure. Also, after the interconnect via structure is formed in the field area independent from the device area, the lower-layer metals (M0 metal and M1 metal) between the first transistor and the second transistor may be interconnected, thereby making the signal transmission through the field area independent of the signal transmission through internal structures such as source/drain metal and metal vias.

In some embodiments, the semiconductor structure provided by the embodiments of the present disclosure may be detected using detection analysis instruments, such as a scanning electron microscope (SEM), a transmission electron microscope (TEM), a scanning transmission electron microscope (STEM), and the like. Taking TEM as an example, as to the semiconductor structure provided by the embodiments of the present disclosure, the interconnection between the first source/drain metal and the second source/drain metal may be detected by means of TEM foil.

In some embodiments, embodiments of the present disclosure provide a semiconductor structure prepared using the preparation method in one or more of the above-described embodiments. The semiconductor structure includes: a first transistor; a second transistor, the first transistor and the second transistor being disposed opposite to each other; where the first source/drain metal of the first transistor is communicated with the second source/drain metal of the second transistor through an interconnect via structure, the interconnect via structure passes through the first interlayer dielectric layer of the first transistor and the second interlayer dielectric layer of the second transistor. In an embodiment, the structure of the semiconductor structure may be shown in FIGS. 1 to 33 above.

In some embodiments, embodiments of the present disclosure provide an electronic equipment. The electronic equipment includes: a circuit board and a semiconductor device as described in the above embodiments, the semiconductor device being disposed on the circuit board. The semiconductor device includes the semiconductor structure as described above. The structure of the semiconductor structure may be seen in FIGS. 1 to 33 above.

In the above-described embodiments, the description of each embodiment has its own emphasis, and for parts not described in detail in a certain embodiment, please refer to the related description of other embodiments.

The foregoing is merely a specific embodiment of the present disclosure in one embodiment, but the scope of protection of the present disclosure is not limited thereto, and any variations or substitutions that can be easily conceived by those skilled in the art within the technical scope of the present disclosure should be covered within the scope of protection of the present disclosure. Therefore, the scope of protection of the present disclosure should be subject to the scope of protection of the claims.

1. A preparation method of a semiconductor structure, comprising:
forming an active structure on a semiconductor substrate, wherein the active structure includes a first active structure and a second active structure;
forming a first transistor based on the first active structure; wherein the first transistor includes a first source/drain structure, a first source/drain metal, and a first interlayer dielectric layer;
performing flipping on the first transistor and removing the semiconductor substrate; and
forming a second transistor based on the second active structure; wherein the second transistor includes a second source/drain structure, a second source/drain metal, and a second interlayer dielectric layer;
wherein the first source/drain metal is communicated with the second source/drain metal through an interconnect via structure, the interconnect via structure passes through the first interlayer dielectric layer and the second interlayer dielectric layer.

2. The preparation method according to claim 1, wherein the forming a first transistor based on the first active structure, comprises:
forming the first source/drain structure based on the first active structure;
depositing a semiconductor material on the first active structure and the first source/drain structure to form the first interlayer dielectric layer; and
forming the first source/drain metal after the first interlayer dielectric layer is formed;
wherein the forming a second transistor based on the second active structure, comprises:
forming the second source/drain structure based on the second active structure;
depositing a semiconductor material on the second active structure and the second source/drain structure to form the second interlayer dielectric layer;
wherein the first interlayer dielectric layer and the second interlayer dielectric layer are disposed in a stack;
forming the second source/drain metal after the second interlayer dielectric layer is formed;
etching the second interlayer dielectric layer and the first interlayer dielectric layer in turn to form a first deep groove; and
depositing a metallic material within the first deep groove to form the interconnect via structure.

3. The preparation method according to claim 2, wherein the forming the first source/drain metal after the first interlayer dielectric layer is formed, comprises:
etching the first interlayer dielectric layer until the first source/drain structure is exposed to form a first groove, wherein one end of the first deep groove is communicated with the first groove; and
depositing a metallic material within the first groove to form the first source/drain metal;
wherein the forming the second source/drain metal after the second interlayer dielectric layer is formed, comprises:
etching the second interlayer dielectric layer until the second source/drain structure is exposed to form a second groove, wherein the other end of the first deep groove is communicated with the second groove; and
depositing a metallic material within the second groove to form the second source/drain metal;
wherein a first end of the interconnect via structure is connected to the first source/drain metal, a second end of the interconnect via structure is connected to the second source/drain metal.

4. The preparation method according to claim 2, wherein the forming the first source/drain metal after the first interlayer dielectric layer is formed, comprises:
etching the first interlayer dielectric layer until the first source/drain structure is exposed to form a first groove;
depositing a metallic material within the first groove to form the first source/drain metal; and
forming a first metal interconnect layer on the first source/drain metal;
wherein the forming the second source/drain metal after the second interlayer dielectric layer is formed, comprises:
etching the second interlayer dielectric layer until the second source/drain structure is exposed to form a second groove;
depositing a metallic material within the second groove to form the second source/drain metal; and
forming a second metal interconnect layer on the second source/drain metal; wherein a first end of the interconnect via structure is connected to the first metal interconnect layer, a second end of the interconnect via structure is connected to the second metal interconnect layer.

5. The preparation method according to claim 2 4, wherein the first active structure is a first fin structure, the second active structure is a second fin structure; wherein the etching the second interlayer dielectric layer and the first interlayer dielectric layer in turn to form a first deep groove, further comprises:
removing at least one fin in the second fin structure; and
etching the second interlayer dielectric layer, the first interlayer dielectric layer, and a fin in the first fin structure corresponding to the at least one fin in the second fin structure in turn until the first source/drain structure is exposed to form the first deep groove;
wherein a stacking direction of the semiconductor structures is a first direction, all of fin structures in the second fin structure are arranged in a second direction, the second direction is perpendicular to the first direction.

6. The preparation method according to claim 5, wherein the etching the second interlayer dielectric layer, the first interlayer dielectric layer, and a fin in the first fin structure corresponding to the at least one fin in the second fin structure in turn until the first source/drain structure is exposed to form the first deep groove, comprises:
etching the second interlayer dielectric layer, the first interlayer dielectric layer, the fin of the first fin structure corresponding to at least one fin of the second fin structure, and the first source/drain structure until the first source/drain metal is exposed to form the first deep groove.

7. The preparation method according to claim 2 4, wherein the first active structure is at least one of a first nanosheet and/or a first nanowire structure, the second active structure is at least one of a second nanosheet or a second nanowire structure; wherein the etching the second interlayer dielectric layer and the first interlayer dielectric layer in turn to form a first deep groove, further comprises:
etching the second interlayer dielectric layer, the first interlayer dielectric layer, and the at least one of the first nanosheet and/or the first nanowire structure in turn to form the first deep groove.

8. The preparation method according to claim 2 4, wherein the etching the second interlayer dielectric layer and the first interlayer dielectric layer in turn to form a first deep groove, comprises:
performing a gate cut process on a first gate structure of the first transistor and a second gate structure of the second transistor to form a gate cut-off structure; and
lithographing the first interlayer dielectric layer of the first transistor and the second interlayer dielectric layer of the second transistor based on a lithography area self-aligned to the gate cut-off structure to form the first deep groove.

9. The preparation method according to claim 1, wherein the forming a first transistor based on the first active structure, comprises:
forming the first source/drain structure based on the first active structure;
depositing a semiconductor material on the first active structure and the first source/drain structure to form the first interlayer dielectric layer; and
forming the first source/drain metal and a first interconnect via structure after the first interlayer dielectric layer is formed; wherein the first interconnect via structure at least partially passes through the first interlayer dielectric layer;
wherein the forming a second transistor based on the second active structure, comprises:
forming the second source/drain structure based on the second active structure;
depositing a semiconductor material on the second active structure and the second source/drain structure to form the second interlayer dielectric layer;
wherein the first interlayer dielectric layer and the second interlayer dielectric layer are disposed in a stack; and
forming the second source/drain metal and a second interconnect via structure after the second interlayer dielectric layer is formed; wherein the second interconnect via structure at least partially passes through the second interlayer dielectric layer; wherein the first interconnect via structure is communicated with the second interconnect via structure; the first interconnect via structure and the second interconnect via structure are combined to form the interconnect via structure.

10. The preparation method according to claim 9, wherein the forming the first source/drain metal and a first interconnect via structure after the first interlayer dielectric layer is formed, comprises:
etching the first interlayer dielectric layer until the first source/drain structure is exposed to form a first groove;
etching the first interlayer dielectric layer to form a third groove; and
depositing a metallic material within the first groove and the third groove to form the first source/drain metal and the first interconnect via structure respectively; wherein one end of the third groove is communicated with the first groove;
wherein the forming the second source/drain metal and a second interconnect via structure after the second interlayer dielectric layer is formed, comprises:
etching the first interlayer dielectric layer until the second source/drain structure is exposed to form a second groove;
etching the second interlayer dielectric layer until the first interconnect via structure is exposed to form a fourth groove; and
depositing a metallic material within the second groove and the fourth groove to form the second source/drain metal and the second interconnect via structure respectively; wherein one end of the fourth groove is communicated with the second groove, the other end of the fourth groove is communicated with the third groove.

11. The preparation method according to claim 9, wherein the forming the first source/drain metal and a first interconnect via structure after the first interlayer dielectric layer is formed, comprises:
etching the first interlayer dielectric layer until the first source/drain structure is exposed to form a first groove;
etching the first interlayer dielectric layer to form a third groove;
depositing a metallic material within the first groove and the third groove to form the first source/drain metal and the first interconnect via structure respectively; and
forming a first metal interconnect layer on the first source/drain metal;
wherein the forming the second source/drain metal and a second interconnect via structure after the second interlayer dielectric layer is formed, comprises:
etching the second interlayer dielectric layer until the second source/drain structure is exposed to form a second groove;
etching the first interlayer dielectric layer to form a third groove;
depositing a metallic material within the first groove and the third groove to form the first source/drain metal and the first interconnect via structure respectively; and
forming a second metal interconnect layer on the second source/drain metal; wherein a first end of the first interconnect via structure is connected to the first metal interconnect layer, a second end of the first interconnect via structure is connected to a first end of the second interconnect via structure, a second end of the second interconnect via structure is connected to the second metal interconnect layer.

12. The preparation method according to claim 2, wherein the forming an active structure on a semiconductor substrate, comprises:
forming the active structure on the semiconductor substrate, wherein the active structure includes a device area and a field area which are arranged in a third direction;
the third direction is an extension direction of the active structure, the third direction is perpendicular to a the first direction and a the second direction; wherein the device area is used to form the first source/drain structure and the second source/drain structure; and
removing the first active structure located in the field area of the active structure, wherein the second active structure in the field area is retained;
wherein the depositing a semiconductor material on the first active structure and the first source/drain structure to form the first interlayer dielectric layer, comprises:
depositing the semiconductor material on the retained second active structure in the field area to form the first interlayer dielectric layer;
wherein performing flipping on the first transistor and removing the semiconductor substrate, comprises:
performing flipping on the first transistor and removing the semiconductor substrate to expose the second active structure; and
removing the second active structure located in the field area of the active structure to expose the first interlayer dielectric layer;
wherein the depositing a semiconductor material on the second active structure and the second source/drain structure to form the second interlayer dielectric layer, comprises:
depositing a semiconductor material on the exposed first interlayer dielectric layer in the field area to form the second interlayer dielectric layer.

13. The preparation method according to claim 2, wherein
the interconnect via structure is located on one side of the active structure; or,
the interconnect via structure is located on both sides of the active structure; or,
the interconnect via structure is located in the middle of the active structure.

14. A semiconductor structure, which is prepared with the preparation method according to claim 1, comprising:
a first transistor; and
a second transistor, wherein the first transistor-crystal and the second transistor are disposed opposite to each other;
wherein the first source/drain metal of the first transistor is communicated with the second source/drain metal of the second transistor through an interconnect via structure, the interconnect via structure passes through the first interlayer dielectric layer of the first transistor and the second interlayer dielectric layer of the second transistor.

15. A semiconductor device, comprising: a semiconductor structure according to claim 14.

16. An electronic equipment, comprising: a circuit board and a semiconductor device according to claim 15, wherein the semiconductor device is disposed on the circuit board.
